(19) United States
(12) Patent Application Publication
(10) Pub. No.: US 2026/0214956 A1
(43) Pub. Date: Jul. 23, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventor: Yutaka TERAO, Hachioji-city (JP)

(73) Assignee: FUJI ELECTRIC CO., LTD., Kawasaki-shi (JP)

(21) Appl. No.: 19/403,658

(22) Filed: Nov. 28, 2025

(30) Foreign Application Priority Data
Jan. 23, 2025 (JP) 2025-010176
Jun. 25, 2025 (JP) 2025-107386

(51) Int. Cl. H10D 64/01; H10D 30/01; H10D 30/66; H10D 62/832

(52) U.S. Cl. CPC H10D 64/01366; H10D 30/0291; H10D 30/66; H10D 62/8325

(57) ABSTRACT

A method of manufacturing a silicon carbide semiconductor device, including: preparing a semiconductor substrate containing silicon carbide and forming a semiconductor region therein, to consequently have a surface thereof oxidized; etching the oxidized surface using a gas free of oxygen atoms, thereby exposing a silicon carbide surface at the surface of the semiconductor substrate; depositing a silicon-containing layer containing silicon atoms and free of oxygen atoms to a thickness of 1 nm or more on the surface of the silicon carbide, without exposing the semiconductor substrate to an atmosphere containing oxygen atoms; depositing a silicon oxide film constituting a gate insulating film on the silicon-containing layer; performing a first heat treatment in an atmosphere containing nitrogen atoms, thereby nitriding the silicon-containing layer and the silicon carbide surface; performing a second heat treatment, thereby promoting oxidation of the silicon-containing layer; and subsequently forming a gate electrode on the gate insulating film.

### CROSS REFERENCE TO RELATED APPLICATIONS

This application is based upon and claims the benefit of priority of the prior Japanese Patent Application No. 2025-010176, filed on January 23, 2025, and the prior Japanese Patent Application No. 2025-107386, filed on June 25, 2025, the entire contents of which are incorporated herein by reference.

### BACKGROUND OF THE INVENTION

### 1. Field of the Invention

Embodiments of the disclosure relate to a silicon carbide semiconductor device and method of manufacturing a silicon carbide semiconductor device.

### 2. Description of the Related Art

Japanese Laid-Open Patent Publication No. 2020-27894 describes a technique of forming a relatively silicon-rich layer on a channel formation region, then forming a termination layer in which excess silicon atoms in the relatively silicon-rich layer are terminated with a group V element by a heat treatment using a gas containing a group V element, and forming a gate insulating film on the termination layer to reduce the interface state density. Japanese Laid-Open Patent Publication No. 2021-86896 describes a technique of reducing the interface state density by forming a nitride termination layer at an interface between a gate insulating film and a channel formation region by a nitriding treatment and then removing excess nitride atoms in the nitride termination layer by a heat treatment with carbon dioxide gas. Japanese Laid-Open Patent Publication No. 2023-604 describes a technique of evaluating a nitrogen atom concentration distribution and a carbon atom concentration distribution in a vicinity of an interface of an insulated gate structure by SIMS. Japanese Patent No. 5608840 also describes a technique similar to that of Japanese Laid-Open Patent Publication No. 2023-604.

### SUMMARY OF THE INVENTION

According to an embodiment of the present disclosure, a method of manufacturing a silicon carbide semiconductor device, includes: as a first process, preparing a semiconductor substrate containing silicon carbide and forming a semiconductor region therein, to have a surface of the semiconductor substrate oxidized; as a second process, etching the oxidized surface of the semiconductor substrate using a gas free of oxygen atoms, thereby exposing a silicon carbide surface at the surface of the semiconductor substrate; as a third process, depositing a silicon-containing layer containing silicon atoms and free of oxygen atoms to a thickness of 1 nm or more on the surface of the silicon carbide, without exposing the semiconductor substrate to an atmosphere containing oxygen atoms; as a fourth process, depositing a silicon oxide film constituting a gate insulating film on the silicon-containing layer; as a fifth process, performing a first heat treatment in an atmosphere containing nitrogen atoms, thereby nitriding the silicon-containing layer and the silicon carbide surface; as a sixth process, performing a second heat treatment, thereby promoting oxidation of the silicon-containing layer; and as a seventh process, forming a gate electrode on the gate insulating film after the sixth process.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment.

FIG. 2 is a flowchart depicting an outline of a method of manufacturing the silicon carbide semiconductor device according to the first embodiment.

FIG. 3 is a cross-sectional view of the silicon carbide semiconductor device according to the first embodiment during manufacture.

FIG. 4 is a cross-sectional view of the silicon carbide semiconductor device according to the first embodiment during manufacture.

FIG. 5 is a cross-sectional view of the silicon carbide semiconductor device according to the first embodiment during manufacture.

FIG. 6 is a cross-sectional view of the silicon carbide semiconductor device according to the first embodiment during manufacture.

FIG. 7 is a cross-sectional view of the silicon carbide semiconductor device according to the first embodiment during manufacture.

FIG. 8 is a cross-sectional view of the silicon carbide semiconductor device according to the first embodiment during manufacture.

FIG. 9 is a cross-sectional view of the silicon carbide semiconductor device according to the first embodiment during manufacture.

FIG. 10 is a table depicting results of measuring interface state densities and donor state densities of first to third examples and first to third comparison examples.

FIG. 11 is a flowchart depicting an outline of a method of evaluating a donor level density in the gate insulating film by a light-assisted C-V method.

FIG. 12 is a characteristic diagram depicting C-V characteristics obtained by the evaluation method depicted in FIG. 11.

FIG. 13 is a cross-sectional view schematically depicting a structure of an optical system mechanism used in an optically assisted C-V method.

FIG. 14 is a table depicting results of calculation of field-effect mobilities and gate threshold voltages of fourth and fifth examples and fourth to sixth comparison examples.

FIG. 15 is a table comparing the number densities of nitrogen atoms in gate insulating films of the second example and the first comparison example.

FIG. 16 is a characteristic diagram depicting results of measurement of nitrogen concentration distribution and carbon concentration distribution in a depth direction from the gate insulating film to the semiconductor substrate of the first comparison example.

FIG. 17 is a characteristic diagram depicting results of measurement of the nitrogen concentration distribution and the carbon concentration distribution in the depth direction from the gate insulating film to the semiconductor substrate of the second example.

FIG. 18 is a comparison diagram depicting the nitrogen concentration distributions depicted in FIGS. 16 and 17 in an overlapping manner.

### DETAILED DESCRIPTION OF THE INVENTION

First, problems associated with the conventional techniques are discussed. In Japanese Laid-Open Patent Publication No. 2020-27894, it is difficult to uniformly form the relatively silicon-rich layer with an optimum thickness, and the reproducibility of the improvement of the gate characteristics is poor. In Japanese Laid-Open Patent Publication No. 2021-86896, since the gate insulating film is formed on a SiC surface, oxidation of the SiC surface is not sufficiently suppressed, and it cannot be said that the interface state density is sufficiently reduced. In Japanese Laid-Open Patent Publication No. 2023-604 and Japanese Patent No. 5608840, there is room for improvement in optimization of the nitrogen atom concentration distribution in the vicinity of the interface of the insulated gate structure.

An overview of an embodiments of the present disclosure is described. (1) A method of manufacturing a silicon carbide semiconductor device according to one aspect of the present disclosure is as follows. A first process of performing a predetermined process of forming a semiconductor region in a semiconductor substrate containing silicon carbide is performed. A second process of etching the surface of the semiconductor substrate oxidized in the first process using a gas free of oxygen atoms and thereby exposing a silicon carbide surface at the surface of the semiconductor substrate is performed. A third process of depositing a silicon-containing layer containing silicon atoms and free of oxygen atoms on the silicon carbide surface without exposing the semiconductor substrate to an atmosphere containing oxygen atoms is performed. A fourth process of depositing a silicon oxide film constituting a gate insulating film on the silicon-containing layer is performed. A fifth process of nitriding the silicon-containing layer and the silicon carbide surface by a first heat treatment in an atmosphere containing nitrogen atoms is performed. A sixth process of promoting oxidation of the silicon-containing layer by a second heat treatment is performed. After the sixth process, a seventh process of forming a gate electrode on the gate insulating film is performed.

According to the above disclosure, oxidation of the silicon carbide surface may be prevented, the interface state density at the interface between the gate insulating film and the semiconductor substrate may be set to 1×10¹¹ cm⁻²/eV or less, and the channel mobility may be increased. In addition, the donor level density in the gate insulating film from the energy at the lower end of the conduction band of silicon carbide to a level deeper by a predetermined energy becomes less than 1×10¹¹ cm⁻² by the second heat treatment, and fluctuation of the gate threshold voltage may be suppressed. Thus, the gate characteristics may be improved.

(2) In the method of manufacturing the silicon carbide semiconductor device according to the present disclosure, in (1) described above, in the third process, the silicon-containing layer may be deposited to a thickness of 2nm or more but not more than 10nm.

According to the above disclosure, by setting the silicon-containing layer to 2nm or more, the silicon carbide surface may be completely covered with the silicon-containing layer, and oxidation of the silicon carbide surface may be prevented. When the silicon-containing layer has a thickness of 10nm or less, increases in takt time may be suppressed.

(3) In the method of manufacturing the silicon carbide semiconductor device according to the present disclosure, in (1) or (2) described above, in the sixth process, the second heat treatment may be performed in an atmosphere containing carbon dioxide.

According to the above disclosure, oxidation of the silicon carbide surface may be prevented.

(4) In the method of manufacturing the silicon carbide semiconductor device according to the present disclosure, in (3) described above, in the sixth process, the second heat treatment may be performed in an atmosphere containing carbon dioxide and nitrogen.

According to the above disclosure, oxidation of the silicon carbide surface may be prevented while maintaining the nitrided structure in the interface between the gate insulating film and the semiconductor substrate.

(5) Further, in the method of manufacturing the silicon carbide semiconductor device according to the present disclosure, in any one of (1) to (4) described above, after forming a silicon-containing nitride layer by nitriding the silicon-containing layer in the fifth process, oxidation of the silicon-containing nitride layer may be promoted in the sixth process.

According to the above disclosure, the nitrogen content of the silicon-containing layer (silicon oxynitride layer) after the first heat treatment and the second heat treatment may be reduced.

(6) Further, in the method of manufacturing the silicon carbide semiconductor device according to the present disclosure, in any one of (1) to (4) described above, after forming a silicon-containing oxide layer by promoting oxidation of the silicon-containing layer in the sixth process, the silicon carbide surface in contact with the silicon-containing oxide layer may be nitrided in the fifth process.

According to the above disclosure, the nitrogen content of the silicon-containing layer (silicon oxynitride layer) after the first heat treatment and the second heat treatment may be reduced.

(7) In the method of manufacturing the silicon carbide semiconductor device according to any one of (1) to (6) described above, in the fifth process, the silicon-containing layer and the silicon carbide surface may be oxynitrided by the first heat treatment using nitric oxide gas or nitrous oxide gas.

According to the above disclosure, the interface state density at the interface between the gate insulating film and the semiconductor substrate may be reduced, and oxidation of the silicon carbide surface may be prevented.

(8) The method of manufacturing the silicon carbide semiconductor device according to the present disclosure may further include, in any one of (1) to (7) described above, depositing a field oxide film on the silicon-containing layer after the third process but before the fourth process, and opening a predetermined portion of the field oxide film to expose the silicon-containing layer in an opening of the field oxide film, and in the fourth process, the silicon oxide film may be deposited on the silicon-containing layer in the opening of the field oxide film.

According to the above disclosure, the interface state density at the interface between the field oxide film and the semiconductor substrate may be reduced.

(9) In the method of manufacturing the silicon carbide semiconductor device according to the present disclosure, in any one of (1) to (8) described above, the first process may include a process of forming a first semiconductor region of a first conductivity type in the semiconductor substrate, a process of forming a second semiconductor region of a second conductivity type between a surface of the semiconductor substrate and the first semiconductor region, and a process of selectively forming a third semiconductor region of the first conductivity type between the surface of the semiconductor substrate and the second semiconductor region, and in the third process, the silicon-containing layer may be deposited on a region of the second semiconductor region between the first semiconductor region and the third semiconductor region.

The above disclosure may be applied to a MOSFET.

(10) A silicon carbide semiconductor device according to one aspect of the present disclosure is as follows. A semiconductor device includes a semiconductor substrate containing silicon carbide, a gate insulating film provided on a surface of the semiconductor substrate, a gate electrode provided on the gate insulating film, and a surface channel formed in a vicinity of the surface of the semiconductor substrate, facing the gate electrode with the gate insulating film intervening therebetween, the surface channel being formed by gate voltage control applied to the gate electrode. A donor level density in the gate insulating film, from an energy at a lower end of a conduction band (conduction band minimum) of silicon carbide to a level deeper by a predetermined energy less than a band gap of silicon carbide, is less than 1×10¹¹ cm⁻². An interface state density at an interface between the gate insulating film and the semiconductor substrate is 1×10¹¹ cm⁻²/eV or less.

According to the above disclosure, gate characteristics may be improved (increase field-effect mobility, suppress fluctuations in gate threshold voltage, etc.). The donor level density in the gate insulating film may be estimated using the light-assisted CV method.

(11) In the silicon carbide semiconductor device according to the present disclosure, in any one of (1) to (10) described above, the donor level density in the gate insulating film to a level deeper by 2.82eV than an energy of a conduction band minimum of silicon carbide may be less than 1×10¹¹ cm⁻².

According to the above disclosure, the gate characteristics may be improved. The donor level density in the gate insulating film may be estimated by the light-assisted CV method.

(12) In addition, the silicon carbide semiconductor device according to the present disclosure includes, in (10) or (11) described above, a first semiconductor region of a first conductivity type, provided in the semiconductor substrate, a second semiconductor region of a second conductivity type provided between a surface of the semiconductor substrate and the first semiconductor region, and a third semiconductor region of the first conductivity type, selectively provided between the surface of the semiconductor substrate and the second semiconductor region. The surface channel may be formed in a region of the second semiconductor region between the first semiconductor region and the third semiconductor region.

According to the above disclosure, the gate characteristics may be improved.

(13) In the silicon carbide semiconductor device according to the present disclosure, in any one of (10) to (12) described above, a nitrogen concentration distribution in a depth direction from the gate insulating film to the semiconductor substrate has a peak of a Gaussian distribution in which the nitrogen concentration is maximum at a predetermined first depth position, and the nitrogen concentration of the gate insulating film is 6×10²⁰atoms/cm³ or more and the maximum concentration at the interface with the semiconductor substrate due to the peak of the nitrogen concentration distribution. In the nitrogen concentration distribution, a ratio of an integral value of the nitrogen concentration in a range from a second depth position at which a carbon concentration of a carbon concentration distribution in a depth direction from the gate insulating film to the semiconductor substrate is 1% of a carbon concentration of the semiconductor substrate to a third depth position of 3nm in a direction away from the semiconductor substrate, to an integral value of the nitrogen concentration between full widths at half maximum of the peaks may be less than 0.1.

According to the above disclosure, the gate characteristics may be improved.

Findings underlying the present disclosure are discussed. In general, when silicon carbide (SiC) is used as a semiconductor material, the interface state density (crystal defect density) at the interface between an oxide film (SiO₂ film) and a semiconductor is higher than when silicon (Si) is used as a semiconductor material. For this reason, when a MOS gate (insulated gate containing metal-oxide film-semiconductor) is formed using SiC as a semiconductor material, the interface state density of the SiO_{2/}SiC interface is reduced by nitriding the interface between the gate insulating film and the semiconductor (hereinafter referred to as SiO_{2/}SiC interface) by a heat treatment (nitriding treatment) using nitric oxide (NO) gas, nitrous oxide (N₂O) gas, or nitrogen (N₂₎ gas after or before the formation of the SiO₂ film serving as the gate insulating film. However, it cannot be said that the interface state density at the SiO_{2/}SiC interface is sufficiently reduced even by performing the nitriding treatment, and there is room for improvement with respect to problems such as a decrease in channel mobility (field-effect mobility) μ_{FE} and a variation in gate threshold voltage.

In addition, in Japanese Laid-Open Patent Publication No. 2020-27894, it is difficult to uniformly form the relatively silicon-rich layer with an optimum thickness, and the reproducibility of the improvement of the gate characteristics is poor. For example, when the thickness of the relatively silicon-rich layer is thin, the SiC surface cannot be sufficiently covered with the relatively silicon-rich layer, and the effect of suppressing oxidation of the SiC surface is reduced. Therefore, the interface state density of the SiO_{2/}SiC interface (interface between the gate insulating film and the SiC layer) is not sufficiently reduced. On the other hand, when the thickness of the relatively silicon-rich layer is too large, a silicon nitride (SiNx, x is a positive number) region is formed in the gate insulating film in the vicinity of the SiO2/SiC interface, and this SiNx region causes an electron trap level or a hole trap level to be generated in the gate insulating film, whereby the gate characteristics deteriorate. In Japanese Laid-Open Patent Publication No. 2021-86896, since the gate insulating film is formed on the SiC surface, oxidation of the SiC surface is not sufficiently suppressed, and it cannot be said that the interface state density of the SiO2/SiC interface is sufficiently reduced. In Japanese Laid-Open Patent Publication No. 2023-604 and Japanese Patent No. 5608840, there is room for improvement in optimization of the nitrogen atom concentration distribution in the vicinity of the interface of the insulated gate structure.

Thus, a problem to be solved in the present embodiment is to reduce the interface state density at the interface between the insulating film and the semiconductor by preventing the generation of the defect structure derived from the oxidation of the SiC surface, and preferably to provide a method of manufacturing a silicon carbide semiconductor device capable of forming a MOS gate having further improved gate characteristics (for example, further reducing the interface state density at the interface between the gate insulating film and the semiconductor substrate to increase the field-effect mobility, suppressing the fluctuation of the gate threshold voltage due to the nitrogen atoms in the gate insulating film, or the like), having a wide process window, and having high reproducibility.

Embodiments of a method of manufacturing a silicon carbide semiconductor device and a silicon carbide semiconductor device according to the present disclosure will be described in detail with reference to the accompanying drawings. In the description and the accompanying drawings, layers and regions prefixed with n or p mean that majority carriers are electrons or holes, respectively. Further, + and − appended to n and p mean that the dopant concentration is higher or lower, respectively, than layers and regions without + and −. In the following description of the embodiments and the accompanying drawings, the same components are denoted by the same reference numerals, and redundant description thereof will be omitted.

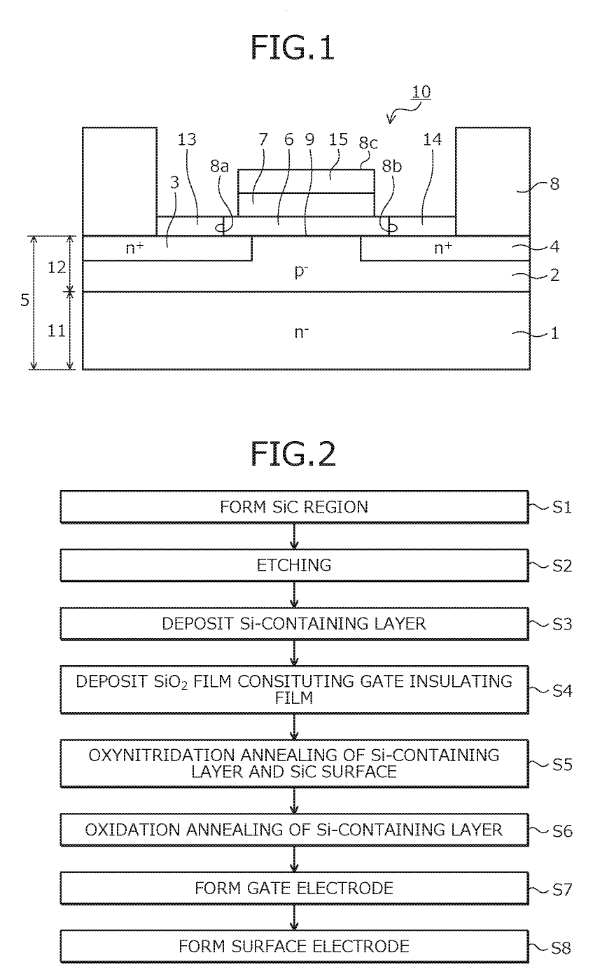

A silicon carbide semiconductor device according to a first embodiment will be described below. FIG. 1 is a cross-sectional view depicting a structure of a silicon carbide semiconductor device according to a first embodiment. The silicon carbide semiconductor device 10 according to the first embodiment depicted in FIG. 1 is a planar (that is, planar gate type) metal oxide semiconductor field effect transistor (MOSFET: MOS field effect transistor including an insulated gate having a three-layer structure of metal-oxide film-semiconductor), includes a gate electrode 7 on a front surface of a semiconductor substrate 5 via a gate insulating film 6, and improves gate characteristics by reducing a donor level density (crystal defect density) in the gate insulating film 6 at a level corresponding to the inside of a band gap of SiC and an interface level density (crystal defect density) at an interface 9 between the gate insulating film 6 and the semiconductor substrate 5 (in the vicinity of an energy level separated by −0.2eV from energy E_{c} of a conduction band minimum of SiC) as much as possible.

The semiconductor substrate 5 is formed by growing by epitaxy an epitaxial layer 11 containing n⁻-type silicon carbide (SiC) and an epitaxial layer 12 containing p⁻-type SiC in this order. The epitaxial layers 11 and 12 constitute an n⁻-type region (first semiconductor region) 1 and a p⁻-type region (second semiconductor region) 2, respectively. The semiconductor substrate 5 has, as a front surface, a first main surface having the epitaxial layer 12 and, as a back surface, a second main surface having the epitaxial layer 11. A starting substrate (bulk substrate: not depicted) containing SiC used at the time of epitaxial growth of the epitaxial layers 11 and 12 may remain on the back surface of the semiconductor substrate 5. The epitaxial layer 11 itself may be the starting substrate. The back surface of the semiconductor substrate 5 is fixed to a reference potential (minimum potential) of the silicon carbide semiconductor device 10 or a circuit on which the silicon carbide semiconductor device 10 is mounted.

Between the front surface of the semiconductor substrate 5 and the p-type region 2, an n⁺-type source region (third semiconductor region) 3 and an n⁺-type drain region 4 are selectively provided, apart from each other, so as to be exposed on the front surface of the semiconductor substrate 5 and to be in contact with the p-type region 2. The n+-type source region 3 and the n+-type drain region 4 are diffused regions formed by ion implantation in the epitaxial layer 12. A portion of the p−-type epitaxial layer 12 excluding the n+-type source region 3 and the n+-type drain region 4 constitutes the p−-type region 2. The p−-type region 2 reaches the front surface of the semiconductor substrate 5 between the n+-type source region 3 and the n+-type drain region 4 adjacent to each other. On the front surface of the semiconductor substrate 5, a gate electrode 7 is provided via a gate insulating film 6 on a portion of the p−-type region 2 sandwiched between the n+-type source region 3 and the n+-type drain region 4 (a portion where a surface channel is formed when the MOSFET is on).

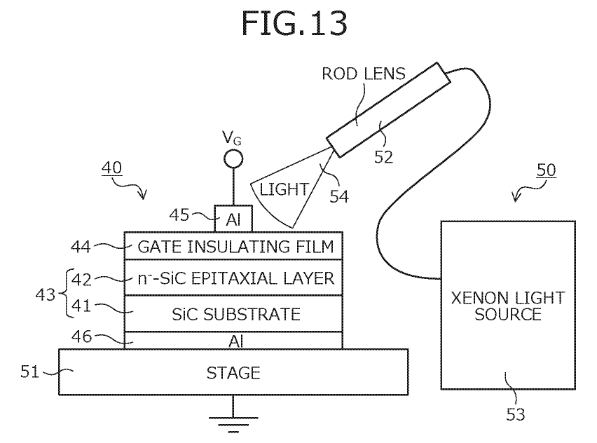

The gate insulating film 6 is a silicon oxide (SiO₂₎ film, and an interface 9 between the gate insulating film 6 and the semiconductor substrate 5 contains nitrogen atoms by a nitriding treatment. The gate insulating film 6 in a vicinity of the interface 9 to a level deeper than the energy E_{c} of the conduction band minimum of SiC by the energy E_{d} of predetermined light 54. The donor level density is as low as less than about 1×10¹¹ cm⁻². The predetermined energy E_{d} of the light 54 is the energy of the light 54 with which the gate insulating film 6 is irradiated when the donor level density in the gate insulating film 6 is obtained by the light-assisted C-V (capacitance-voltage) method (refer to FIG. 13 described later).

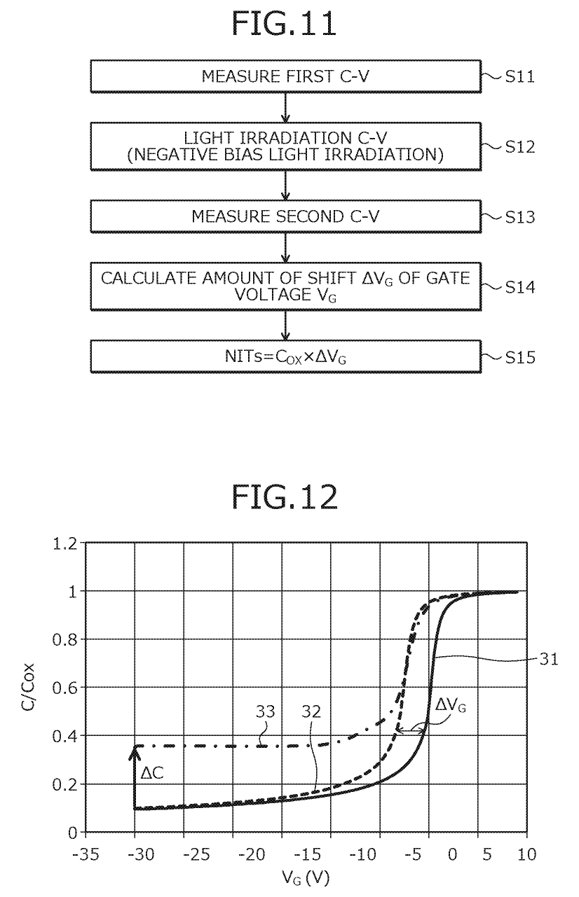

The light-assisted C-V method is a C-V measurement using photoexcitation, and by comparing the C-V characteristic obtained after the irradiation of the gate insulating film 6 with the light 54 with the C-V characteristic before the light irradiation, the charge trap density (fixed charge density) generated in the gate insulating film 6 by the light irradiation may be estimated (refer to FIGS. 11 to 13 described later). Generally, as the light 54 used in the light-assisted C-V method, light having lower energy than the band gap E_{g} of SiC is used in order to estimate the trapped charge density in the band gap E_{g} of SiC.

Specifically, for example, an easily available xenon (Xe) lamp may be used as the light source 53 of the light 54 used in the light-assisted C-V method. When a Xe lamp is used as the light source 53 of the light 54 used in the light- assisted C-V method, for example, the energy Ed of the predetermined light 54 may be set to the energy (=2.82eV) of a Xe ray having a wavelength of 440nm ±10nm by using a band-pass filter. In this way, the donor level density in the gate insulating film 6 in the energy band from the energy Ec at the lower end of the conduction band of SiC estimated by the optically assisted C-V method to the level deeper by 2.82eV becomes less than about 1×1011cm−2.

For example, by using, for example, a xenon (Xe) light source as the light source 53 of the light 54 used in the optically assisted C-V method, it is possible to stably output the light 54 in a predetermined wavelength band with high luminance at a small light emitting point by adjusting the optical path length by a mirror or dispersing the light by a filter. Therefore, it is possible to accurately obtain the donor level density in the gate insulating film 6. Specifically, for example, a xenon light source “MAX-303” manufactured by Asahi Spectra Co., Ltd. may be used as the light source 53 of the light 54 used in the light-assisted C-V method. In the first embodiment, the donor level density in the gate insulating film 6 from the energy E_{c} at the lower end of the conduction band of SiC to a level deeper than the energy E_{c} by the energy E_{d} of the predetermined light 54 is set to be lower than the upper limit value, whereby the variation of the gate threshold voltage during gate negative bias (when a negative voltage is applied to the gate electrode 7) may be suppressed to an allowable level (for example, −0.1V or less in absolute value).

The interface state density at the interface 9 between the gate insulating film 6 and the semiconductor substrate 5 is equal to or lower than the lower limit value (detection limit) of the detection accuracy by the high-low C-V method, and is specifically 1×10¹¹cm⁻²/eV or less. Thus, the channel mobility of the MOSFET may be prevented from decreasing. The interlayer insulating film 8 is provided on the entire front surface of the semiconductor substrate 5 and covers the gate electrode 7. The gate insulating film 6 may extend between the semiconductor substrate 5 and the interlayer insulating film 8. Between the front surface of the semiconductor substrate 5 and the gate insulating film 6, a field oxide film (not depicted) may be disposed in the entire region (not depicted) excluding an active region (a region in which cells (functional units) of the MOSFET are disposed), or the interlayer insulating film 8 may also serve as the field oxide film. The field oxide film is assimilated with the gate insulating film 6 at a portion adjacent to the gate insulating film 6.

Contact holes 8a and 8b penetrate through the interlayer insulating film 8 and the gate insulating film 6 in a depth direction and reach the semiconductor substrate 5. The contact hole 8c penetrates through the interlayer insulating film 8 in the depth direction and reaches the gate electrode 7. The source electrode 13 is in ohmic contact with the n⁺-type source region 3 via the contact hole 8a. The drain electrode 14 is in ohmic contact with the n⁺-type drain region 4 via the contact hole 8b. The gate metal wiring layer 15 is formed on an extending portion of the gate electrode 7 in the contact hole 8c, and functions as a gate finger. The gate electrode 7 is, for example, a polysilicon (poly-Si) layer. The extending portion (gate polysilicon wiring layer) of the gate electrode 7 functions as a gate finger serving as a coupling portion with a gate pad (not depicted).

The source electrode 13 and the drain electrode 14 each have a stacked structure in which, for example, an ohmic electrode film and an electrode film containing aluminum (Al) (hereinafter referred to as an Al electrode film) are stacked in this order. The gate metal wiring layer 15 and the gate pad are Al electrode films. The ohmic electrode film is, for example, a nickel silicide (NixSiy, x and y are positive numbers) film or a titanium silicide (TiSi) film, and is in ohmic contact with the front surface of the semiconductor substrate 5. The Al electrode film is an Al film or an Al alloy film. A barrier metal (not depicted) may be provided between the ohmic electrode film and the Al electrode film. The barrier metal has a function of preventing atomic diffusion and mutual reaction between regions facing each other with the barrier metal intervening therebetween or between metals. The outermost surface of the front surface of the semiconductor substrate 5 is covered with a passivation film (not depicted).

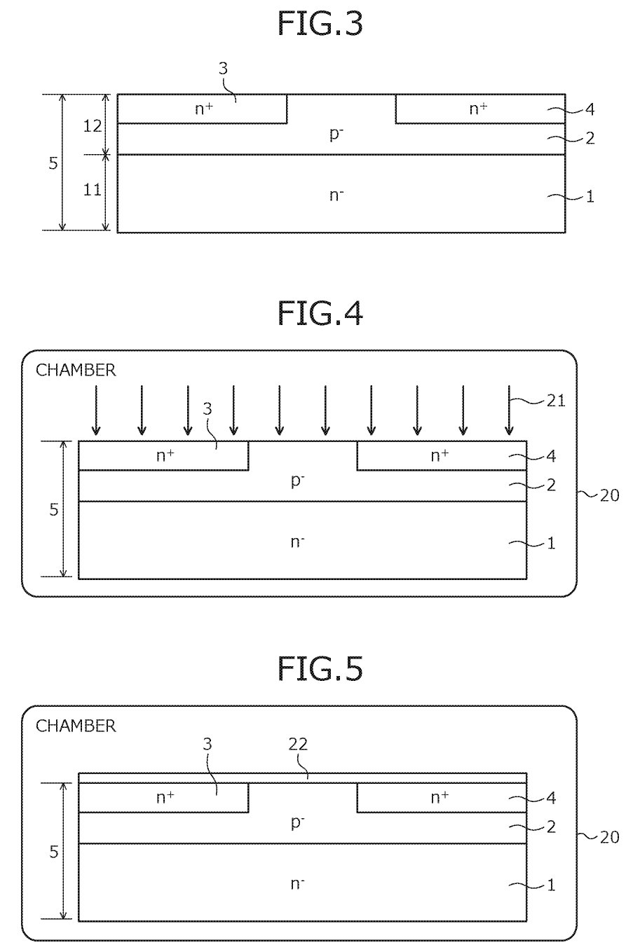

A method of manufacturing the silicon carbide semiconductor device according to the first embodiment will be described. FIG. 2 is a flowchart depicting an outline of a method of manufacturing the silicon carbide semiconductor device according to the first embodiment. FIGS. 3, 4, 5, 6, 7, 8, and 9 are cross-sectional views of the silicon carbide semiconductor device according to the first embodiment during manufacture. First, as depicted in FIG. 3, on the front surface of an n-type starting substrate (starting wafer: not depicted) containing SiC, the n⁻-type epitaxial layer 11 doped with, for example, nitrogen (N) and serving as the n⁻-type region 1 and a p⁻-type epitaxial layer 12 doped with, for example, Al and serving as the p⁻-type region 2 are grown by epitaxy in this order to fabricate the semiconductor substrate 5. The semiconductor substrate 5 may be obtained by removing the starting substrate by grinding from the back surface side (epitaxial layer 11 side) to a position corresponding to a product thickness used for the silicon carbide semiconductor device 10, or may be obtained by leaving the starting substrate. The p⁻-type epitaxial layer 12 may be formed directly on the n⁺-type starting substrate without forming the n⁻-type epitaxial layer 11. Alternatively, the p⁻-type region 2 may be formed by ion-implanting a p-type dopant into the n⁻-type epitaxial layer 11.

Next, by photolithography and ion implantation of a dopant of a predetermined conductivity type, diffused regions (hereinafter, referred to as SiC regions) of the predetermined conductivity type such as the n⁺-type source region 3 and the n⁺-type drain region 4 are formed in the epitaxial layer 12 in the front surface region at the front surface of the semiconductor substrate 5 (step S1: first process). In the ion implantation for forming the SiC region, for example, phosphorus (P) may be used as an n-type dopant, and for example, Al may be used as a p-type dopant. The n⁻-type semiconductor substrate 5 may be prepared, and the p⁻-type region 2 may be selectively formed in the semiconductor substrate 5 by ion implantation in the process at step S1. In this case, a portion of the n⁻-type semiconductor substrate 5 excluding the p⁻-type region 2, the n⁺-type source region 3, and the n⁺-type drain region 4 constitutes the n⁻-type region 1.

The process at step S1 is a process of forming a semiconductor region (the SiC region, the p−-type region 2, or the like) in the semiconductor substrate 5. Between the various steps of the process at step S1, a general cleaning process such as a so-called RCA cleaning (wet cleaning using a mixed acid of a strong acid and a strong base) or a hydrofluoric acid (HF) cleaning is performed to remove organic substances, particles, ion contamination, and the like generated in the various processes to clean the semiconductor substrate 5 and send the cleaned semiconductor substrate 5 to the manufacturing line of the next step. Therefore, in the process at step S1, the semiconductor substrate 5 is oxidized by being exposed to the atmosphere, being immersed in a cleaning liquid (acidic solution), or being exposed to oxygen plasma or active oxygen during the formation of the SiO₂ layer serving as an ion implantation mask. A crystal defect structure including oxygen (O) atoms and excess carbon (C) atoms is generated at the front surface of the semiconductor substrate 5 due to SiC oxidation. Therefore, as depicted in FIG. 4, the front surface of the semiconductor substrate 5 is etched 21 to remove the crystal defect structure together with the surface layer of the semiconductor substrate 5 at the front surface thereof, and a clean surface (SiC surface (silicon carbide surface)) is exposed on the front surface of the semiconductor substrate 5 (step S2: second process).

The etching 21 in the process at step S2 is, for example, H₂ etching performed in a state where the semiconductor substrate 5 is exposed to a gas atmosphere containing hydrogen (H₂) gas at a purity of about 3% to 100% and the semiconductor substrate 5 is heated to a temperature of about 1300 degrees C or more but not more than 1500 degrees C in a general heating furnace (hereinafter, referred to as a chamber 20). In a case where the gas atmosphere of the H₂ etching is a mixed gas atmosphere containing a gas other than the H₂ gas, the gas other than the H₂ gas is a noble gas that is less likely to react with other atoms, such as argon (Ar), neon (Ne), or krypton (Kr), so that the semiconductor substrate 5 may be etched 21 without oxidation, and reoxidation of the front surface of the semiconductor substrate 5 during the etching process may be suppressed. The gas atmosphere of the H₂ etching may be preferably set to, for example, a pressure of about 0.5Torr or more but not more than 760Torr, and a gas flow rate of about 100sccm or more depending on the processing capability (exhaust capability) of the etching apparatus.

The etching 21 at step S2 may be H₂ plasma etching instead of H₂ etching. When the etching 21 in the process at step S2 is H₂ plasma etching, the front surface of the semiconductor substrate 5 is etched 21 by, for example, inserting the semiconductor substrate 5 into the chamber 20 of a general plasma processing apparatus and exposing the front surface of the semiconductor substrate 5 to H₂ plasma generated using H₂ gas as a source gas or irradiating the front surface of the semiconductor substrate 5 with an active species (radicals or ions) of hydrogen (H) in the H₂ plasma. At this time, after the semiconductor substrate 5 is inserted into the chamber 20, the inside of the chamber 20 is evacuated to reduce the pressure (preferably, for example, vacuum evacuation to about 0.5Pa or less), the amount of O₂ in the chamber 20 is reduced as much as possible, H₂ gas is introduced, and H₂ plasma is generated at a predetermined atmospheric pressure by appropriately controlling the evacuation rate in the chamber 20.

The H₂ plasma may be generated after evacuating the chamber 20 two or three times. In this case, for example, after the inside of the chamber 20 is evacuated, introduction of a noble gas such as Ar into the chamber 20 and evacuation of the inside of the chamber 20 are alternately repeated, and then H₂ plasma is generated. Thus, the H₂ plasma etching may be performed after reducing the amount of residual O₂ and moisture (H₂O) in the chamber 20. H₂ plasma may be generated by using a general plasma generation technique such as capacitively coupled plasma (CCP), inductively coupled plasma (ICP), or electron cyclotron resonance (ECR) plasma. When H₂ plasma etching using CCP is performed, the pressure in the chamber 20 may be set to, for example, about 1Pa to 100Pa, which is a general pressure. However, when the pressure is set to 5Pa or less, preferably 0.5Pa or less, uniformity of plasma and uniformity of etching are easily obtained.

The H₂ plasma by the CCP plasma is generated using an RF (radio frequency) power source of a general band (for example, 13.56MHz). The H₂ plasma by the ICP plasma is generated by causing an RF current of 13.56MHz, 27.12MHz, or 40.68MHz to flow through a coil wound around a hollow cylindrical discharge tube to generate an electric field by electromagnetic induction in the discharge tube, and ionizing a part of the H₂ gas in the discharge tube by collision with electrons generated in the discharge tube by RF discharge in the coil and accelerated by the electric field in the discharge tube. H₂ plasma by ECR plasma is generated using microwaves (2.45GHz). As a source gas of H₂ plasma, a H₂ gas having a purity of 100% may be used, or a H₂ gas diluted with a noble gas such as Ar may be used.

The etching 21 in the process at step S2 may be noble gas plasma etching instead of H₂ etching. The noble gas plasma etching may be performed in the same manner as the H₂ plasma etching except that a noble gas such as Ar, Ne, or Kr is used as a source gas of plasma instead of the H₂ gas. Also in the noble gas plasma etching, reoxidation of the front surface of the semiconductor substrate 5 may be suppressed by using a noble gas that is less likely to react with other atoms. The noble gas plasma etching is sputter etching that etches the surface layer of the front surface of the semiconductor substrate 5 in atomic units by ionizing and colliding a noble gas. Therefore, it is preferable to adjust the discharge power (RF power) for plasma generation and the bias voltage (RF voltage) applied to the semiconductor substrate 5 to avoid excessive ion collision with the front surface of the semiconductor substrate 5.

Damage caused at the front surface of the semiconductor substrate 5 by ion collisions of the noble gas plasma etching may be recovered by heating the semiconductor substrate 5 in an atmosphere free of oxygen (O₂) before the process at step S3 described later. The atmosphere free of oxygen is a state in which the inside of the chamber 20 is evacuated, or a state in which the inside of the chamber 20 is filled with an inert gas atmosphere such as Ar gas or an inert gas atmosphere containing hydrogen gas. This heat treatment is preferably performed in a heating atmosphere at a temperature of, for example, 800 degrees C or higher at which a damage recovery effect of the SiC surface is obtained and about 1000 degrees C or lower at which deposition of graphene (excess carbon) due to Si sublimation does not occur. At this time, the semiconductor substrate 5 after the noble gas plasma etching is exposed to a heating atmosphere without being exposed to an oxygen atmosphere to perform the heat treatment.

Next, as depicted in FIG. 5, in the same chamber 20 as that in the process at step S2, a silicon (Si) layer or a silicon-containing layer (hereinafter, collectively referred to as a Si-containing layer 22) is deposited on the front surface of the semiconductor substrate 5 without exposing the semiconductor substrate 5 to oxygen such as the atmosphere, and the entire front surface of the semiconductor substrate 5 is completely covered with the Si-containing layer 22 (step S3: third process). The Si-containing layer 22 has a composition free of oxygen atoms. The Si-containing layer 22 functions as a cap film that prevents oxidation of the front surface (SiC surface) of the semiconductor substrate 5. By setting the thickness of the Si-containing layer 22 to, for example, 2 nm or more, the front surface of the semiconductor substrate 5 may be completely covered with the Si-containing layer 22 regardless of variations in the thickness of the Si-containing layer 22, and subsequent oxidation of the front surface of the semiconductor substrate 5 may be prevented. It suffices for in-plane uniformity of the Si-containing layer 22 on the front surface of the semiconductor substrate 5 to be ensured and the front surface of the semiconductor substrate 5 to be completely covered with the Si-containing layer 22, and the thickness of the Si-containing layer 22 may be, for example, 1nm or more but less than 2nm. The Si-containing layer 22 is deposited using a general deposition method such as a low-pressure chemical vapor deposition (LPCVD) method, a plasma (PE: plasma-enhanced) CVD method, or a sputtering method.

For example, in the LPCVD method, a mixed gas of silane (SiH₄) gas and H₂ gas is used as a film forming gas, the pressure in the chamber 20 is set to about 20 Pa or more but not more than 500Pa, and the heating temperature of the semiconductor substrate 5 is set to about 500 degrees C or more but less than 1100 degrees C, thereby depositing a Si layer to be the Si-containing layer 22. When the heating temperature of the semiconductor substrate 5 is set to a high temperature of 1100 degrees C or more, the Si layer is likely to grow in an island shape, and it is difficult to completely cover the SiC surface. For example, the process at step S2 is set to H₂ etching, and immediately after the process at step S2, the conditions in the chamber 20 (supply gas, atmospheric pressure, heating temperature of the semiconductor substrate 5, and the like) are switched to the process conditions at step S3, whereby H₂ etching of the front surface of the semiconductor substrate 5 and deposition of the Si-containing layer 22 using the LPCVD method are performed. This may be performed continuously in the same chamber 20. In addition, the Si-containing layer 22 may be a silicon nitride (SiNx, x is a positive number) film by adding nitrogen (N₂) gas or ammonia (NH₃) gas to the film forming gas of the Si-containing layer 22.

In the PECVD method, an amorphous silicon (a-Si: H) film may be formed as the Si-containing layer 22 by using SiH₄ gas or a mixed gas of SiH₄ gas and H₂ gas as a source gas of plasma, setting a discharge pressure to about 20Pa or more but not more than 100Pa, and setting a heating temperature of the semiconductor substrate 5 to about 200 degrees C or more but not more than 400 degrees C. The process at step S2 is H₂ plasma etching or noble gas plasma etching, and immediately after the process at step S2, the conditions in the chamber 20 (supply gas, atmospheric pressure, heating temperature of the semiconductor substrate 5, etc.) are switched to the process conditions at step S3, whereby the processes at steps S2 and S3 may be continuously performed without exposing the semiconductor substrate 5 to oxygen such as air in the same chamber 20. In addition, the Si-containing layer 22 may be a silicon nitride (SiNx, x is a positive number) film by adding nitrogen (N₂) gas or ammonia (NH₃) gas to the film forming gas of the Si-containing layer 22.

In the sputtering method, an a-Si: H film or a microcrystalline Si film may be formed as the Si-containing layer 22 by using a Si target, filling the chamber 20 with an inert gas such as Ar gas, setting the pressure in the chamber 20 to about 0.5Pa or more but not more than 10Pa, and setting the heating temperature of the semiconductor substrate 5 to 600 degrees C or less or not heating the semiconductor substrate 5. Since the front surface of the semiconductor substrate 5 is completely covered with the Si-containing layer 22 as described above, the front surface (SiC surface) of the semiconductor substrate 5 is not oxidized even when the semiconductor substrate 5 is exposed to the atmosphere. Therefore, the subsequent processing may be performed in a state where the semiconductor substrate 5 is exposed to the atmosphere.

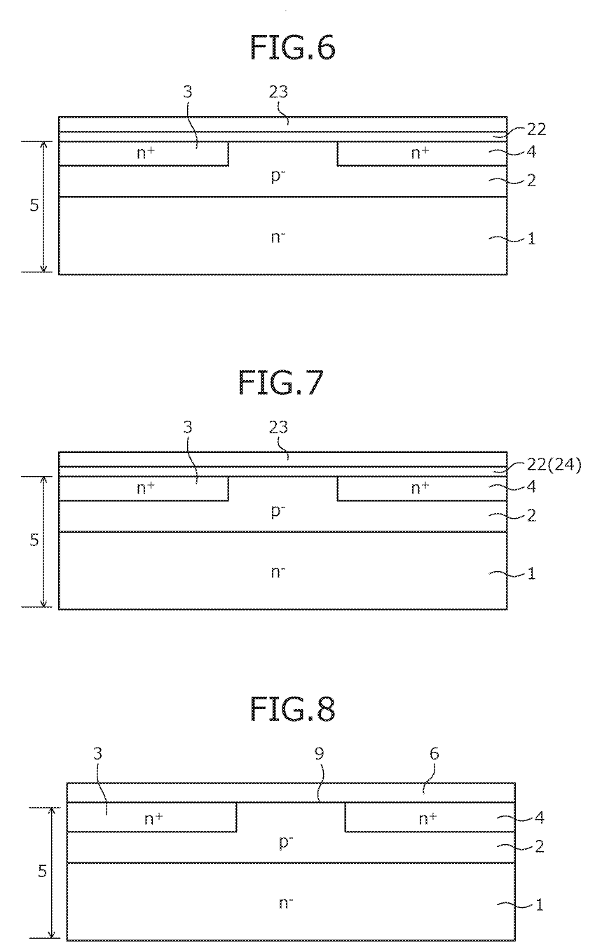

Next, as depicted in FIG. 6, a silicon oxide (SiO₂) film 23 constituting the gate insulating film 6 is deposited on the Si-containing layer 22 (step S4: fourth process). The SiO₂ film 23 is deposited by a general SiO₂ film deposition method such as a sputtering method, a PECVD method, or a thermal CVD method (i.e. is formed by a method other than thermal oxidation). In the sputtering method, for example, a Si target or a SiO₂ target is used. In the PECVD method, a mixed gas of SiH₄ gas and oxygen (O₂) gas is used as a film forming gas. In the thermal CVD method, a mixed gas of SiH₄ gas and nitrous oxide (N₂O) gas is used as a film forming gas. The SiO₂ film 23 may be deposited using an atomic layer deposition (ALD) method. Although the semiconductor substrate 5 is exposed to an oxygen atmosphere during the treatment at step S4, oxidation of the SiC surface may be prevented by the Si-containing layer 22.

After the process at step S3, a SiO₂ film serving as a field oxide film (not depicted) may be deposited by PECVD, and the field oxide film in the active region may be removed by photolithography and etching to leave the field oxide film only in a region other than the active region, and then the process at step S4 may be performed. In this case, the SiO₂ film 23 is deposited on the Si-containing layer 22 exposed in the opening (active region) of the field oxide film. During the deposition of the field oxide film, the semiconductor substrate 5 is exposed to an oxygen atmosphere as in the process at step S4. Therefore, by depositing the field oxide film after the process at step S3 but before the process at step S4, oxidation of the SiC surface may be prevented by the Si-containing layer 22 at the time of deposition of the field oxide film, and the interface state density of the interface between the field oxide film and the semiconductor substrate 5 may be reduced to the same extent as the interface state density of the interface 9 between the gate insulating film 6 and the semiconductor substrate 5.

Next, as depicted in FIG. 7, the Si-containing layer 22 and the front surface (SiC surface) of the semiconductor substrate 5 are oxynitrided by a heat treatment using a gas containing nitrogen and oxygen (POA: post oxide anneal (hereinafter referred to as oxynitridation annealing (first heat treatment))) (step S5: fifth process). This oxynitridation annealing is a treatment generally performed at the time of forming a MOS gate using SiC as a semiconductor material and reduces the interface state density of the interface 9 between the gate insulating film 6 and the semiconductor substrate 5 by nitriding the interface between the SiO₂ film 23 and the semiconductor substrate 5 and the Si-containing layer 22 therebetween. The gas containing nitrogen and oxygen used in the process at step S5 includes, for example, at least nitric oxide (NO) gas or N₂O gas. For example, the process at step S5 may be oxynitriding annealing at a temperature of about 1150 degrees C or more but not more than 1300 degrees C at atmospheric pressure using a mixed gas of 90% nitrogen (N₂) gas and 10% NO gas.

During the process at step S5, the front surface of the semiconductor substrate 5 is not oxidized because it is completely covered with the Si-containing layer 22. On the other hand, the Si-containing layer 22 is oxynitrided to become the gate insulating film 6. However, since the Si-containing layer 22 is formed to have a thickness of about 2nm or more in order to completely cover the front surface of the semiconductor substrate 5 as described above, the Si-containing layer 22 becomes the silicon oxynitride (SiOxNy, x and y are positive numbers) layer 24 having a high nitrogen (N) content. Since the silicon oxynitride layer 24 having a high nitrogen content is likely to capture (trap) electrons and holes, the charge trap density in the gate insulating film 6 increases during the operation of the MOSFET, and the gate threshold voltage is likely to vary. In the process at step S5, nitriding annealing (first heat treatment) may be performed instead of the oxynitriding annealing. In this case, by the process at step S5, the Si-containing layer 22 becomes a silicon nitride (SixNy, x and y are positive) layer (silicon-containing nitride layer) having a high nitrogen content.

Therefore, next, oxidation of the Si-containing layer 22 (the silicon oxynitride layer 24 having a high nitrogen content) is promoted by a heat treatment (hereinafter, referred to as oxidation annealing (second heat treatment)) to reduce the nitrogen content of the Si-containing layer 22 (step S6: sixth process). By the process at step S6, the oxidation of the Si-containing layer 22 is promoted to reduce the nitrogen content of the Si-containing layer 22, and the Si-containing layer 22 and the SiO₂ film 23 are assimilated to form the gate insulating film 6 as depicted in FIG. 8. When the thickness of the Si-containing layer 22 is about 10nm or less, an increase in takt time may be suppressed. The process at step S6 is performed under a condition that the front surface (SiC surface) of the semiconductor substrate 5 is not oxidized. For example, oxidation annealing in a carbon dioxide (CO₂) gas atmosphere may promote oxidation of the Si-containing layer 22 while suppressing oxidation of the SiC surface. Specifically, the treatment at step S6 may be, for example, oxidation annealing for about 30 minutes or more but not more than 120 minutes at a temperature at which SiC is not oxidized (for example, about 900 degrees C or more but not more than 1300 degrees C, preferably about 1000 degrees C or more but not more than 1200 degrees C) in a gas atmosphere of 100% CO₂ gas.

The process at step S6 may be performed in a mixed gas atmosphere of CO₂ gas and N₂ gas instead of the gas atmosphere of 100% CO₂ gas. By performing the process at step S6 in the mixed gas atmosphere of CO₂ gas and N₂ gas, it is possible to oxidize the nitride structure in the gate insulating film 6 while maintaining the nitride structure (chemical bonding state of N atoms) of the interface 9 between the gate insulating film 6 and the semiconductor substrate 5. The temperature and time of the process at step S6 are preferably adjusted as appropriate according to the crystal plane orientation of the SiC surface (the front surface of the semiconductor substrate 5) on which the MOS gate structure is formed. Oxidation of the SiC surface may be prevented regardless of the processing time at step S6 mainly by appropriately adjusting the processing temperature at step S6. The order of the process at step S5 and the process at step S6 may be changed. That is, after the oxidation of the Si-containing layer 22 is promoted by the treatment (oxidation annealing) at step S6, the Si-containing layer 22 (silicon oxide film (silicon-containing oxide layer)) is oxynitrided by the treatment (oxynitriding annealing) at step S5 to become a silicon oxynitride layer having a low nitrogen content, and the SiC surface (front surface of the semiconductor substrate 5) in contact with the Si-containing layer 22 is oxynitrided.

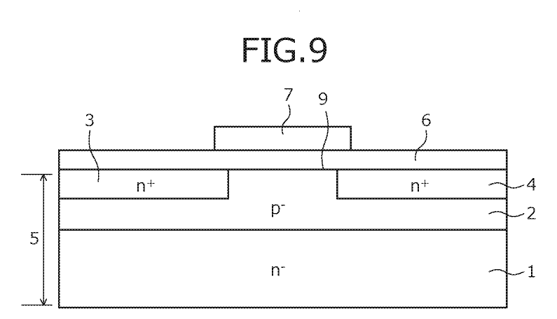

Next, as depicted in FIG. 9, the gate electrode 7 is formed on the surface of the gate insulating film 6 (step S7: seventh process). In the process at step S7, a polysilicon layer is deposited by a general deposition method such as LPCVD, and the polysilicon layer is patterned to leave a portion constituting the gate electrode 7. A gate polysilicon wiring layer functioning as a gate finger may be formed by extending a part of the polysilicon layer to a region other than the active region. Next, the interlayer insulating film 8 is formed on the entire front surface of the semiconductor substrate 5. Next, contact holes 8a and 8b penetrating through the interlayer insulating film 8 and the gate insulating film 6 in the depth direction and a contact hole 8c penetrating through the interlayer insulating film 8 in the depth direction are formed.

Next, an aluminum (Al) film or an Al alloy film is formed on the front surface of the semiconductor substrate 5 and patterned to form the source electrode 13, the drain electrode 14, the gate metal wiring layer 15, and a gate pad (not depicted) as front surface electrodes (step S8). The source electrode 13 is electrically connected to the n⁺-type source region 3 in the contact hole 8a. The drain electrode 14 is electrically connected to the n⁺-type drain region 4 in the contact hole 8b. The gate polysilicon wiring layer is formed on the front surface of the semiconductor substrate 5 via a field oxide film (not depicted). The gate metal wiring layer 15 is formed on the gate polysilicon interconnection layer in contact hole 8c, and functions as the gate finger.

A field oxide film is formed at an arbitrary timing after the process at step S3 but before the formation of the interlayer insulating film 8. The interlayer insulating film 8 may also serve as a field oxide film. Thereafter, the entire front surface of the semiconductor substrate 5 is covered with a passivation film (not depicted) for protection. Then, the passivation film is partially removed by photolithography and etching to expose portions to be electrode pads (a source pad, a drain pad, and a gate pad) in different openings of the passivation film, thereby completing silicon carbide semiconductor device 10 (lateral MOSFET) in FIG. 1. A portion of the source electrode 13 exposed in the opening of the passivation film functions as a source pad. A portion of the drain electrode 14 exposed in the opening of the passivation film functions as a drain pad.

In the method of manufacturing the silicon carbide semiconductor device according to the first embodiment (refer to FIG. 2), a vertical MOSFET having a planar gate structure may be fabricated instead of the lateral MOSFET. In this case, the epitaxial layers 11 and 12 that become the n⁻-type region 1 and the p⁻-type region 2 are grown by epitaxy on the front surface of the n⁺-type starting substrate that becomes the n⁺-type drain region during the process at step S1, and the drain electrode is formed on the back surface of the n⁺-type starting substrate during the process at step S8. The n⁺-type drain region may be formed by ion implantation of an n-type dopant at the back surface of the semiconductor substrate 5 before the process at step S8.

In the method of manufacturing the vertical MOSFET having the planar gate structure, a trench gate structure may be formed instead of the planar gate structure. In this case, in the process at step S1, the SiC regions (the n⁺-type source region and the p⁺-type contact region) are selectively formed in the surface region of the front surface of the semiconductor substrate 5, and a gate trench that penetrates through the n⁺-type source region and the p⁻-type region 2 (the p⁻-type base region) from the front surface of the semiconductor substrate 5 and terminates in the n⁻-type region 1 (the n⁻-type drift region) is formed. The n⁺-type SiC region may be formed after the formation of the gate trench. Thereafter, the processes at steps S2 to S8 described above may be performed.

To form the gate trench, first, an oxide film (SiO₂) serving as an etching mask is deposited on the front surface of the semiconductor substrate 5 by, for example, a CVD method, and a portion of the oxide film corresponding to a formation region of the gate trench is opened by photolithography and dry etching using, for example, a mixed gas containing a trifluoromethane (CHF₃) gas, a CF₄ gas, and an Ar gas. After the resist mask is removed, a gate trench is formed by dry etching using a mixed gas containing sulfur hexafluoride (SF₆) gas, O₂ gas, and Ar gas by an ICP etching apparatus, for example, using the oxide film as a mask.

Then, the oxide film used as the etching mask of the gate trench is removed by, for example, hydrofluoric acid (HF). After the removal of the oxide film, a heat treatment for controlling the cross-sectional shape of the gate trench may be performed. Thereafter, in the process at step S2, the inner wall of the gate trench and the front surface of the semiconductor substrate 5 are etched (etching 21). In the processes at steps S3 and S4, the Si-containing layer 22 and the SiO₂ film 23 are deposited in this order along the inner wall of the gate trench and the front surface of the semiconductor substrate 5. When the SiO₂ film 23 is deposited on the sidewalls of the gate trench, it is preferable to use a thermal CVD (LPCVD) method in a low-pressure atmosphere.

In the process at step S5, the Si-containing layer 22, the inner wall (SiC surface) of the gate trench, and the front surface (SiC surface) of the semiconductor substrate 5 are oxynitrided. In the process at step S6, oxidation of the Si-containing layer 22 (the silicon oxynitride layer 24 having a high nitrogen content) is promoted, and the Si-containing layer 22 and the SiO₂ film 23 are assimilated to form the gate insulating film, as in the case of fabricating (manufacturing) the silicon carbide semiconductor device 10 depicted in FIG. 1 described above. The gate insulating film is formed over the inner wall of the gate trench and the front surface of the semiconductor substrate 5.

In the process at step S7, the trench gate structure is formed by embedding a polysilicon layer constituting the gate electrode on the gate insulating film inside the gate trench. In the process at step S8, the source electrode and the gate pad are formed on the front surface of the semiconductor substrate 5, and the drain electrode is formed at the back surface of the semiconductor substrate 5 (the back surface of the n⁺-type starting substrate constituting the n⁺-type drain region). The n⁺-type drain region may be formed by ion implantation of an n-type dopant at the back surface of the semiconductor substrate 5 before the process at step S8. Thus, a MOSFET having a trench gate structure is completed.

As described above, according to the first embodiment, after the SiC surface is exposed by etching the crystal defect structure due to oxidation of the front surface of the semiconductor substrate, the Si-containing layer is deposited on the SiC surface without exposing the semiconductor substrate to an oxygen atmosphere. By completely covering the SiC surface with the Si-containing layer, oxidation of the SiC surface may be prevented, and the interface state density at the interface between the gate insulating film and the semiconductor substrate may be reduced. Thus, the channel mobility may be increased, so that the gate characteristics may be improved. Further, even when the thickness of the Si-containing layer is increased in order to completely cover the SiC surface with the Si-containing layer, the donor level density in the gate insulating film may be reduced by converting the Si-containing layer into a silicon oxynitride layer having a low nitrogen content by oxidation annealing under a condition in which the SiC surface is not oxidized to form the gate insulating film. As a result, fluctuation of the gate threshold voltage may be suppressed, and the gate characteristics may be improved.

Further, according to the first embodiment, etching of the front surface of the semiconductor substrate (exposure of the SiC surface), deposition of the Si-containing layer on the SiC surface, and oxidation annealing of the Si-containing layer may be added to a general gate process and thus, application to the general gate process is easy. Further, by increasing the thickness of the Si-containing layer, the SiC surface may be completely covered with the Si-containing layer regardless of variations in the thickness of the Si-containing layer, and oxidation of the SiC surface may be reliably prevented. Even when the thickness of the Si-containing layer is increased, the oxidation of only the Si-containing layer is promoted by the oxidation annealing under the condition that the SiC surface is not oxidized, whereby the nitrogen content of the gate insulating film including the oxynitrided Si-containing layer may be reduced to improve the gate characteristics while preventing the oxidation of the SiC surface. Therefore, a method of manufacturing a silicon carbide semiconductor device having a wide process window and high reproducibility may be provided.

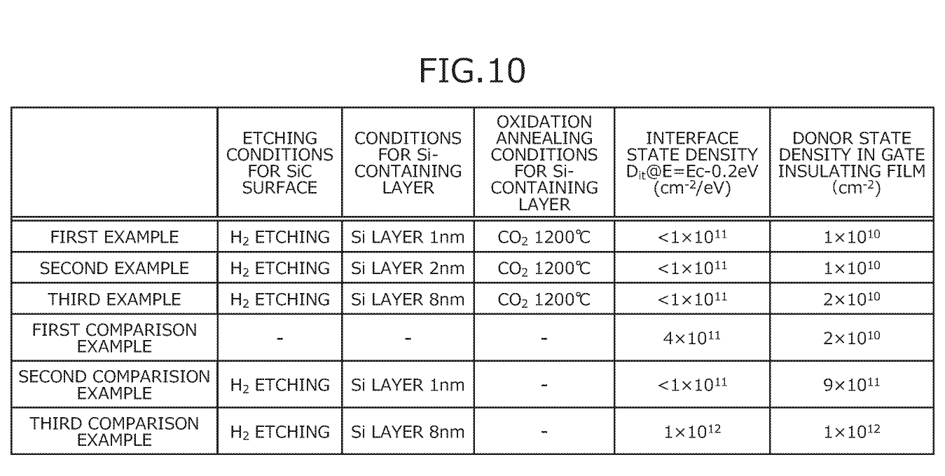

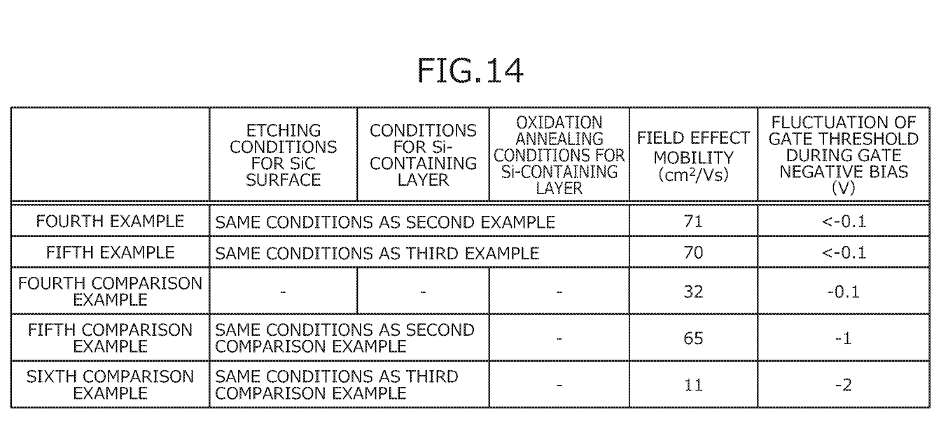

Using the MOS capacitor 40 (refer to FIG. 13), the relationship between the interface state density at the interface 9 between the gate insulating film 6 and the semiconductor substrate 5 and the donor state density in the gate insulating film 6 was verified for the silicon carbide semiconductor device 10 (refer to FIG. 1) according to the first embodiment described above. FIG. 10 is a table depicting results of measuring interface state densities and donor state densities of the first to third examples and first to third comparison examples. FIG. 11 is a flowchart depicting an outline of a method of evaluating the donor level density in the gate insulating film by the light-assisted C-V method. FIG. 12 is a characteristic diagram depicting C-V characteristics obtained by the evaluation method depicted in FIG. 11. FIG. 13 is a cross-sectional view schematically depicting the structure of an optical system mechanism used in the optically assisted C-V method. FIG. 14 is a table depicting results of calculation of field-effect mobilities and gate threshold voltages of fourth and fifth examples and fourth to sixth comparison examples.

First, the gate insulating film 44 and the Al electrode layer 45 were deposited in this order on the front surface of the n-type semiconductor substrate 43 containing SiC, and the Al electrode layer 46 was deposited on the back surface of the semiconductor substrate 43, thereby fabricating (manufacturing) the MOS capacitor 40 (refer to FIG. 13, hereinafter referred to as the first to third examples and the first to third comparison examples). In each of the first to third examples and the first to third comparison examples, the semiconductor substrate 43 is formed by performing CMP (Chemical Mechanical Polishing) on the front surface of a starting substrate 41 containing SiC (depicted as a SiC substrate in FIG. 13) and then growing by epitaxy an n⁻-type epitaxial layer 42 (depicted as an n ^{- -}SiC epilayer in FIG. 13) on the front surface of the starting substrate 41 to a thickness of 5μm. The semiconductor substrate 43 has, as a front surface, a main surface having the epitaxial layer 42 and, a back surface, a main surface having the starting substrate 41 (a back surface of the starting substrate 41) is. Starting substrate 41 is a 4H—SiC (four-layer periodic hexagonal crystal of silicon carbide) substrate. The front surface of the starting substrate 41 is a (0001) plane having an off angle of about 4 degrees in the <11-20> direction, that is, a so-called Si plane.

The gate insulating film 44 was formed on the entire front surface of the semiconductor substrate 43. The gate insulating film 44 was formed under different conditions in the first to third examples and the first to third comparison examples as described later. The Al electrode layers 45 and 46 were deposited using a vacuum deposition method by resistance heating. The Al electrode layer 45 serving as a gate electrode was formed having, in a plan view, a circular shape with a diameter of 200μm on the gate insulating film 44 using a metal mask, and had a surface area smaller than that of the front surface of the semiconductor substrate 43. The Al electrode layer 46 was deposited on the entire back surface of the semiconductor substrate 43. The starting substrate 41, the epitaxial layer 42, the semiconductor substrate body 43, the gate insulating film 44, and the Al electrode layer 45 of the first to third examples correspond to the epitaxial layers 11 and 12, the semiconductor substrate body 5, the gate insulating film 6, and the gate electrode 7 of the silicon carbide semiconductor device 10 depicted in FIG. 1, respectively. In the first to third examples, the gate insulating film 44 was formed according to the method of manufacturing the silicon carbide semiconductor device according to the first embodiment (refer to FIG. 2) while changing the deposition conditions of the Si layer (corresponds to step S3 in FIG. 2, the conditions of the Si-containing layer in FIG. 10).

Specifically, in the first example, in the formation of the gate insulating film 44, first, the semiconductor substrate 43 was subjected to RCA cleaning, and the front surface of the semiconductor substrate 43 was subjected to H₂ etching in the chamber 20 (corresponds to step S2 in FIG. 2, etching conditions of the SiC surface in FIG. 10). Then, in the same chamber 20, a Si layer was deposited on the front surface of the semiconductor substrate 43 to about 1nm using the LPCVD method (corresponds to step S3 in FIG. 2, conditions of the Si-containing layer in FIG. 10), and HTO was deposited on the Si layer by about 50nm using the LPCVD method (corresponds to step S4 in FIG. 2). Then, the Si layer and the front surface of the semiconductor substrate 43 (the interface between the Si layer and the semiconductor substrate 43) were subjected to oxynitridation annealing (corresponds to step S5 in FIG. 2), and then the silicon oxynitride layer (oxynitrided Si layer) was subjected to oxidation annealing with CO₂ gas (corresponds to step S6 in FIG. 2, oxidation annealing conditions of the Si-containing layer in FIG. 10), whereby the silicon oxynitride layer and the HTO were assimilated to form the gate insulating film 44.

The H₂ etching of the front surface of the semiconductor substrate 43 was performed for 5 minutes by using H₂ gas, setting the pressure in the chamber 20 to 700Pa, and setting the heating temperature of the semiconductor substrate 43 to 1450 degrees C. After the H₂ etching, the pressure in the chamber 20 and the heating temperature of the semiconductor substrate 43 were lowered to 200Pa and 700 degrees C, respectively, and a mixed gas of SiH₄ gas at 20sccm and H₂ gas at 80sccm was introduced into the chamber 20 as a film forming gas to deposit the Si layer for 20 seconds. HTO was deposited (deposition of SiO₂) by lowering the pressure in the chamber 20 and the heating temperature of the semiconductor substrate 43 to 0.2Pa and 600 degrees C, respectively, and introducing a mixed gas of SiH₄ gas and O₂ gas as a film forming gas. The oxynitride annealing was performed at a temperature of 1250 degrees C for 60 minutes under atmospheric pressure using a mixed gas of 90% N₂ gas and 10% NO gas. The oxidation annealing was performed in an atmosphere of 100% CO₂ gas at a temperature of 1200 degrees C for 60 minutes.

The second example was fabricated in the same manner as the first example except that the deposition time and the thickness of the Si layer serving as the gate insulating film 44 were 30 seconds and 2nm, respectively. The third example was fabricated in the same manner as the first example except that the deposition time and the thickness of the Si layer serving as the gate insulating film 44 were set to 120 seconds and 8nm, respectively. In the first comparison example, the semiconductor substrate 43 was subjected to RCA cleaning, HTO was deposited as the gate insulating film 44 on the front surface of the semiconductor substrate 43, and then the HTO and the front surface of the semiconductor substrate 43 (the interface between the HTO and the semiconductor substrate 43) were subjected to oxynitride annealing. In the first comparison example, the gate insulating film 44 is formed by a general gate process when SiC is used as a semiconductor material, and H₂ etching, deposition of a Si layer, and oxidation annealing of a silicon oxynitride layer, which are performed in the first example, are not performed. The RCA cleaning conditions, HTO deposition conditions, and oxynitride annealing conditions of the first comparison example are the same as those of the first example. The second and third comparison examples were fabricated in the same manner as in the first and third examples, respectively, except that the oxidation annealing of the silicon oxynitride layer was not performed.

FIG. 10 depicts the results of calculation of the interface state density Dᵢₜ (the interface state density of the energy level E (=E_{c}−0.2eV) separated by 0.2eV within the band gap of SiC from the energy E_{c} of the conduction band minimum of SiC) of the interface between the gate insulating film 44 and the semiconductor substrate 43 in each of the first to third examples and the first to third comparison examples described above, and the donor state density in the gate insulating film 44 to a level deeper than the energy E_{c} of the conduction band minimum of SiC by the energy E_{d} of the predetermined light 54 (hereinafter, simply referred to as the donor state density in the gate insulating film 44). The interface state density at the interface between the gate insulating film 44 and the semiconductor substrate 43 was calculated by the high-low C-V method using the high-frequency C-V characteristics at 1MHz and the low-frequency C-V characteristics at 100Hz based on the measured values of the first to third examples and the first to third comparison examples. The donor level density in the gate insulating film 44 was evaluated (estimated) by the light-assisted C-V method. The predetermined energy E_{d} corresponds to the energy (photon energy for exciting electrons at a predetermined donor level to the conduction band of SiC) of the light 54 with which the gate insulating film 44 is irradiated using the optical system mechanism 50 depicted in FIG. 13.

A method of evaluating the donor level density in the gate insulating film 44 by the light-assisted C-V method will be described with reference to FIGS. 11 to 13. As depicted in FIG. 13, the optical system mechanism 50 using the light-assisted C-V method includes a stage 51, a rod lens 52, and a light source 53. An object to be evaluated by the optical system mechanism 50 (here, the first to third examples and the first to third comparison examples) is placed on the stage 51. The light source 53 was a xenon light source using a xenon lamp with a power consumption of 300W. The rod lens 52 has a mechanism for emitting the light 54 incident from the light source 53 to the evaluation object at a wide angle. First, the semiconductor chip (the semiconductor substrate 43 on which the MOS capacitor 40 is fabricated) is placed on the stage 51 of the optical system mechanism 50 with the front surface facing upward. Next, the first C-V measurement is performed to obtain the first C-V characteristic 31 of the initial MOS capacitor 40 (step S11). The first C-V characteristic 31 of the initial MOS capacitor 40 is a C-V characteristic in which charges (electrons and holes) are not trapped in the gate insulating film 44.

The C-V measurement is a method of measuring the current flowing through the MOS capacitor 40 while changing the gate voltage _{VG}, and calculating the capacitance C of the MOS capacitor 40 from the minimum capacitance Cₘᵢₙ when the gate negative bias is maintained to the maximum capacitance Cₘₐₓ when the gate positive bias is applied (when the positive voltage is applied to the Al electrode layer 45 as the gate electrode) to obtain the C-V characteristic (C-V curve). In the equilibrium state in which the gate negative bias is maintained, the depletion layer width hardly changes, and the depletion layer capacitance C_{d} is saturated. Since the generation source of holes in the n-type semiconductor substrate 43 is in the depletion layer or the surface of the depletion layer, it takes time to generate a hole accumulation layer and the capacitance C of the MOS capacitor 40 is saturated to the minimum capacitance Cₘᵢₙ. As the gate positive bias is increased, electrons are accumulated in the surface region of the front surface of the semiconductor substrate 43, and the capacitance C of the MOS capacitor 40 is saturated with the oxide film capacitance (capacitance of the gate insulating film 44) Cₒₓ. Therefore, the maximum capacitance Cₘₐₓ of the MOS capacitor 40 when the gate is positively biased is equal to the oxide film capacitance Cₒₓ (that is, C/Cₒₓ=1).

Next, the MOS capacitor 40 is discharged and charged (light irradiation C-V) using the light-assisted C-V method (step S12). Specifically, in the process at step S12, in a state in which the gate negative bias to the MOS capacitor 40 (negative voltage application to the Al electrode layer 45 serving as the gate electrode) is maintained and a depletion layer is spreads from the interface between the gate insulating film 44 and the semiconductor substrate 43; the gate insulating film 44 on the front surface of the semiconductor substrate 43 on the stage 51 is irradiated with the light 54 of the light source 53 from the rod lens 52 of the optical system mechanism 50 from the side opposite to the semiconductor substrate 43 side (negative bias light irradiation). For example, the gate insulating film 44 may be irradiated with light 54 having a wavelength of 440nm ±10nm for 5 minutes using a xenon light source as the light source 53. Thereafter, the negative bias light irradiation is stopped, and the gate voltage V_{G} of the MOS capacitor 40 is increased from the gate negative bias to the gate positive bias at which the maximum capacitance Cₘₐₓ of the MOS capacitor 40 is obtained. At this time, the current flowing through the MOS capacitor 40 may be measured to calculate the capacitance C of the MOS capacitor 40, and the light irradiation C-V characteristic 33 of the MOS capacitor 40 may be obtained.

In response to the energy E_{d} (=2.82eV) of the light 54, electrons from the energy E_{c} at the lower end of the conduction band of SiC to a level deeper by the energy E_{d} of the light 54 are excited to the conduction band of SiC, and the electrons excited to the conduction band escape from the SiO_{2/}SiC interface (the interface between the gate insulating film 44 and the semiconductor substrate 43) to the starting substrate 41 side by the electric field in the depletion layer, whereby positive charges are accumulated at the SiO_{2/}SiC interface and the capacitance C of the MOS capacitor 40 increases in the gate negative bias region. At this time, when a donor level that may be excited to the conduction band of SiC by the light 54 is present in the gate insulating film 44 in the vicinity of the interface between the gate insulating film 44 and the n⁻-type epitaxial layer 42, electrons are emitted and holes are trapped (captured) in the gate insulating film 44 to become fixed charges. Due to the influence of the positive charges accumulated at the SiO_{2/}SiC interface as the trapped holes (positive charges) in the gate insulating film 44, the light irradiation C-V characteristic 33 of the MOS capacitor 40 has the capacitance C increased by ΔC in the gate negative bias region and shifted (translated) in the negative direction of the gate voltage axis (horizontal axis in FIG. 12) as compared with the initial first C-V characteristic 31. The influence of the trapped holes in the gate insulating film 44 on the gate voltage _{VG} of the MOS capacitor 40 (shift in the negative direction of the gate voltage axis) is maintained in the subsequent gate operation of the MOS capacitor 40.

Next, the second C-V measurement is performed to obtain the second C-V characteristic 32 of the MOS capacitor 40 (step S13). The second C-V characteristic 32 of the MOS capacitor 40 is shifted in the negative direction of the gate voltage axis as compared with the initial first C-V characteristic 31 due to the influence of trapped holes in the gate insulating film 44. Next, the shift amount ΔV_{G} of the gate voltage VG between the first C-V characteristic 31 and the second C-V characteristic 32 is calculated (step S14). The shift amount (potential difference) ΔV_{G} of the gate voltage _{VG} calculated in the process at step S14 is the charge amount of holes (donor level) captured in the gate insulating film 44 in the process at step S12. Therefore, the donor level density NITs (=Cₒₓ×ΔV_{G}) in the gate insulating film 44 to a level deeper than the energy E_{c} of the conduction band minimum of SiC by the predetermined energy E_{d} of the light 54 may be calculated based on the shift amount ΔV_{G} of the gate voltage VG calculated in the process at step S14 and the oxide film capacitance Cₒₓ (step S15). The processes at steps S11 to S15 described above were performed for each of the first to third examples and the first to third comparison examples.

As depicted in FIG. 10, in the first to third examples, the interface state density at the interface between the gate insulating film 44 and the semiconductor substrate 43 was reduced to be equal to or less than the lower limit value (detection limit) of the detection accuracy by the high-low C-V method, as compared with the first comparison example using a general gate process. In addition, in the first to third examples, the donor level density in the gate insulating film 44 was reduced to a level equal to or lower than that of the first comparison example. On the other hand, in the second comparison example in which the Si layer was deposited with the same thickness as that in the first example before the deposition of the HTO film but the Si layer was not subjected to oxidation annealing, the interface state density at the interface between the gate insulating film 44 and the semiconductor substrate 43 was reduced as compared with the first comparison example, but the donor state density in the gate insulating film 44 was increased. In the third comparison example in which the Si layer was deposited to the same thickness as in the third example before the deposition of the HTO film but the Si layer was not subjected to oxidation annealing, both the interface state density at the interface between the gate insulating film 44 and the semiconductor substrate 43 and the donor state density in the gate insulating film 44 were increased as compared with the first comparison example.

That is, when the front surface of the semiconductor substrate 43 is only covered with the Si-containing layer and the oxidation annealing of the Si-containing layer is not performed as in the second and third comparison examples, the donor level density in the gate insulating film 44 increases. When the thickness of the Si-containing layer covering the front surface of the semiconductor substrate 43 increases as in the third comparison example, both the interface state density at the interface between the gate insulating film 44 and the semiconductor substrate 43 and the donor state density in the gate insulating film 44 increase. On the other hand, as in the first to third examples, it was confirmed that, by covering the front surface of the semiconductor substrate 43 with the Si-containing layer (corresponds to the Si-containing layer 22 in FIG. 5) before deposition of HTO third comparison example (corresponds to the process at step S3 in FIG. 2) and subjecting the Si-containing layer to oxidation annealing (corresponds to the process at step S6 in FIG. 2), both the interface state density at the interface between the gate insulating film 44 and the semiconductor substrate 43 and the donor state density in the gate insulating film 44 were reduced even when the thickness of the Si-containing layer was relatively increased.

As described above, even when the Si-containing layer is thickly deposited to a thickness of about 2nm or more on the front surface of the semiconductor substrate 43 and the Si-containing layer is oxynitrided to form a silicon oxynitride layer having a high nitrogen content, the nitrogen content of the Si-containing layer may be reduced by promoting the oxidation of the Si-containing layer (silicon oxynitride layer having a high nitrogen content) by the subsequent oxidation annealing. Therefore, while the thickness of the Si-containing layer is increased to about 2nm or more to completely cover the front surface of the semiconductor substrate 43 with the Si-containing layer to prevent oxidation of the front surface of the semiconductor substrate 43, oxidation of the Si-containing layer is promoted by oxidation annealing and thus, both the interface state density at the interface between the gate insulating film 44 and the semiconductor substrate 43 and the donor state density in the gate insulating film 44 may be reduced as in the first to third examples. Although not depicted, even when the order of the oxynitridation annealing of the Si layer and the SiC surface and the oxidation annealing of the Si-containing layer is changed, the same results as in the first to third examples are obtained.

FIG. 14 depicts the results of calculating the peak values (maximum values) of the field-effect mobilities of the lateral MOSFETs (hereinafter referred to as the fourth and fifth examples and the fourth to sixth comparison examples) simulated based on the interface state densities depicted in FIG. 10. The fourth and fifth examples correspond to the lateral MOSFET (refer to FIG. 1) fabricated according to the method of manufacturing the silicon carbide semiconductor device according to the first embodiment (refer to FIG. 2). In the fourth and fifth examples, the semiconductor substrate 5 is formed by washing (RCA washing, HF washing) and drying a 4H—SiC substrate, and then growing by epitaxy the n⁻-type epitaxial layer 11 constituting the n⁻-type region 1 and the p⁻-type epitaxial layer 12 constituting the p⁻-type region 2 on the 4H—SiC substrate. The 4H—SiC substrate is a starting substrate for the epitaxial growth of the epitaxial layers 11 and 12. The front surface of the 4H—SiC substrate is a (0001) plane having an off angle of about 4 degrees in the <11-20> direction, that is, a so-called Si plane.

The dopant of the n−-type epitaxial layer 11 was nitrogen (N). The dopant and acceptor concentrations NA of the p−-type epitaxial layer 12 were aluminum (Al) and 1×10¹⁶/cm³, respectively. The n⁺-type source region 3 and the n⁺-type drain region 4 are SiC regions formed by ion implantation of phosphorus (P). The gate insulating films 6 of the fourth and fifth examples were formed under the same conditions and by the same method as those of the gate insulating films 44 of the second and third examples described above (refer to FIG. 10). In the formation of the gate insulating film 6, after the deposition of the Si layer, a SiO₂ film constituting the field oxide film was deposited to a thickness of 700nm by PECVD, and the field oxide film in the active region was removed by photolithography and etching to leave the field oxide film only in a region other than the active region. Then, an HTO film constituting the gate insulating film 6 was deposited. The gate electrode 7 was a polysilicon layer deposited by LPCVD.

The contact holes 8a to 8c were formed by dry etching using boron trichloride (BCl₃) gas by an ICP etching apparatus and wet etching using a buffered hydrofluoric acid (BHF) solution. The source electrode 13 and the drain electrode 14 were formed by stacking an ohmic electrode, a barrier metal, and an Al film in this order. The ohmic electrode was a NixSiy (x and y are positive numbers) film. The barrier metal was a titanium (Ti) film. The gate metal wiring layer 15 and the gate pad were Al films. In the fourth comparison example, a general gate process was applied as in the first comparison example and the other components were fabricated as in the fourth example. In the fifth and sixth comparison examples, the same gate process as in the second and third comparison examples was applied, and the other parts were fabricated in the same manner as in the fourth example. That is, in the fifth and sixth comparison examples, only the process at step S6 (oxidation annealing of the Si-containing layer) in the method of manufacturing the silicon carbide semiconductor device according to the first embodiment is not applied.

As depicted in FIG. 14, in the fourth and fifth examples to which the method of manufacturing the silicon carbide semiconductor device according to the first embodiment described above was applied, the peak value of the field-effect mobility was larger than that in the fourth comparison example using a general gate process. In addition, in the fourth and fifth examples, the gate threshold voltage variation (absolute value) at the time of negative bias was maintained to be equal to or less than that of the fourth comparison example. The gate threshold voltage fluctuation at the time of gate negative bias was a change value (absolute value) of the gate threshold voltage before and after the application of the gate voltage when the gate voltage to the lateral MOSFET was held at the gate negative bias of −15V for 1000 seconds in a state where the stage on which the semiconductor chip (the semiconductor substrate 5 on which the lateral MOSFET is fabricated) is placed is heated to 150 degrees C. The gate threshold voltage variation at the time of gate negative bias in the fourth comparison example was −0.1V, whereas the gate threshold voltage variation at the time of gate negative bias in the fourth and fifth examples was −0.1V or less.

On the other hand, in the fifth and sixth comparison examples in which only the process at step S6 was omitted in the method of manufacturing the silicon carbide semiconductor device according to the first embodiment described above, the gate threshold voltage variation at the time of gate negative bias was significantly larger than that in the first comparison example. Among the fifth and sixth comparison examples, in the fifth comparison example to which the gate process of the second comparison example (refer to FIG. 10) in which the interface state density at the interface between the gate insulating film and the semiconductor substrate was reduced was applied, the field-effect mobility was improved (the peak value of the field-effect mobility was increased) as compared with the first comparison example. Therefore, it was confirmed that while the reduction of the interface state density of the interface 9 between the gate insulating film 6 and the semiconductor substrate 5 greatly contributes to the improvement of the field-effect mobility, the reduction does not contribute to the reduction of the gate threshold voltage fluctuation at the time of gate negative bias. In addition, it was confirmed that the process at step S6 of the method of manufacturing the silicon carbide semiconductor device according to the first embodiment described above greatly contributes to the reduction of the gate threshold voltage fluctuation at the time of gate negative bias.

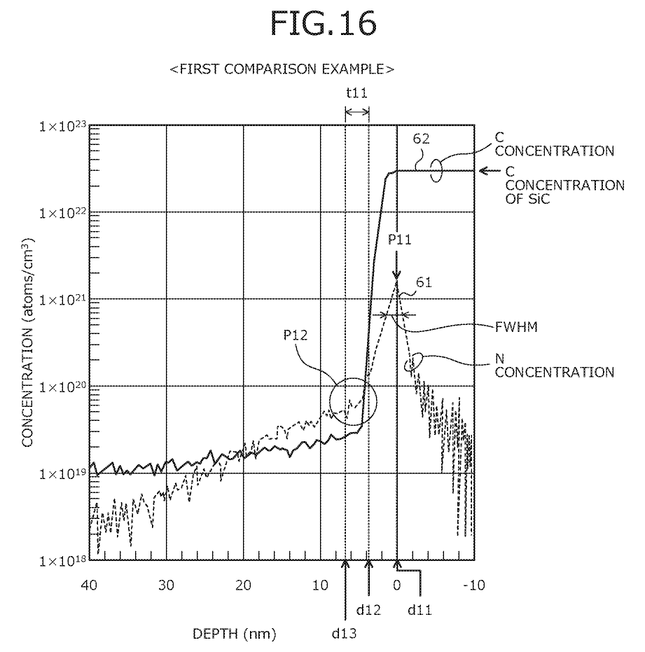

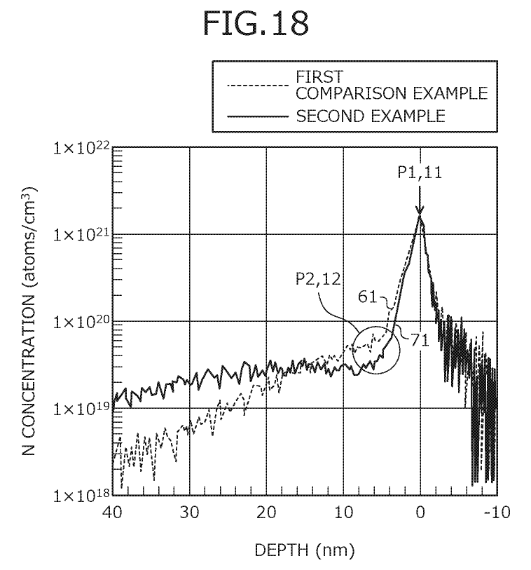

As a second embodiment, a nitrogen (N) concentration distribution in the gate insulating film 6 of the silicon carbide semiconductor device 10 (refer to FIG. 1) according to the first embodiment will be described with reference to FIGS. 16 to 18 to be described later. In the silicon carbide semiconductor device 10 according to the first embodiment, the nitrogen concentration (number density of nitrogen atoms) distribution in the gate insulating film 6 is optimized in the following two ways by applying the method of manufacturing the silicon carbide semiconductor device according to the first embodiment (refer to FIG. 2). The first optimization of the nitrogen concentration distribution in the gate insulating film 6 is that the nitrogen concentration at the interface 9 between the gate insulating film 6 and the semiconductor substrate 5 is maintained at the same level as in the case where the process at step S6 in FIG. 2 is not performed (see the first comparison example in FIGS. 16 and 18). The higher the nitrogen concentration at the interface 9 between the gate insulating film 6 and the semiconductor substrate 5, the easier it is to obtain the effect of reducing the on-resistance due to an increase in channel mobility. Specifically, the nitrogen concentration is preferably, for example, 6×10²⁰ atoms/cm³ or more in measurement by secondary ion mass spectrometry (SIMS).

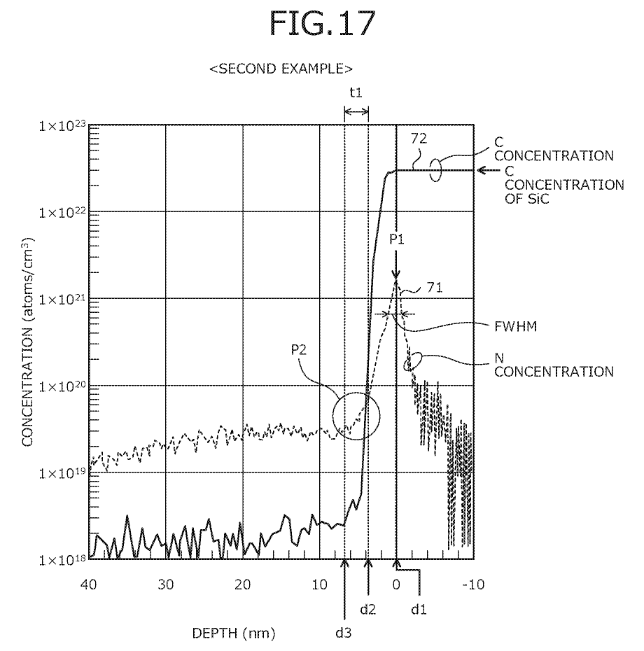

The interface 9 between the gate insulating film 6 and the semiconductor substrate 5 is nitrided by the treatment (oxynitriding annealing) at step S5 depicted in FIG. 2, and the nitrogen concentration is increased at the interface 9 between the gate insulating film 6 and the semiconductor substrate 5 (refer to the second example depicted in FIGS. 17 and 18). A first depth position d1 (depth on the horizontal axis in FIGS. 17 and 18 =0nm) of the maximum nitrogen concentration due to the peak P1 of the nitrogen concentration distribution 71 in the depth direction from the gate insulating film 6 to the semiconductor substrate 5 may be located at the interface 9 between the gate insulating film 6 and the semiconductor substrate 5, or may be located closer to the gate insulating film 6 side or the semiconductor substrate 5 side is than the interface 9. The process at step S5 in FIG. 2 is a process generally performed when forming a MOS gate using SiC as a semiconductor material and is necessary for increasing channel mobility. On the other hand, a portion P2 of the gate insulating film 6 in a vicinity of the interface 9 with the semiconductor substrate 5 is also nitrided by the process at step S5 depicted in FIG. 2, and the nitrogen concentration of the nitrided portion P2 (hereinafter, referred to as the portion P2 in the vicinity of the interface) is also increased.

When the nitrogen concentration of the portion P2 in the vicinity of the interface of the gate insulating film 6 increases to about 5×10¹⁹ atoms/cm³ or more but not more than 1×10²⁰ atoms/cm³ over substantially the entire portion, nitrogen atoms become charge (electron, hole) traps in the gate insulating film 6, which causes a gate threshold voltage variation and a decrease in channel mobility. Therefore, in the present disclosure, as described in the first embodiment, the nitrogen content of the gate insulating film 6 is reduced by the treatment (oxidation annealing) at step S6 in FIG. 2. The inventors have confirmed that the nitrogen concentration of the portion P2 in the vicinity of the interface of the gate insulating film 6 may be reduced while maintaining the nitrogen concentration at the interface 9 between the gate insulating film 6 and the semiconductor substrate 5 by the process at step S6 depicted in FIG. 2 (refer to the second example depicted in FIGS. 17 and 18). The nitrogen concentration distributions 61 and 71 in the depth direction in the first comparison example and the second example in FIG. 18 correspond to the nitrogen concentration distributions in the depth direction in the gate insulating film 6 before and after the process at step S6 in FIG. 2, respectively.

Therefore, the second optimization of the nitrogen concentration distribution in the gate insulating film 6 is that the nitrogen concentration of the portion P2 in the vicinity of the interface of the gate insulating film 6 is lowered as much as possible by the process at step S6 in FIG. 2 to improve the gate characteristics (suppress the fluctuation of the gate threshold voltage and prevent the reduction of the channel mobility). The nitrogen concentration of the portion P2 in the vicinity of the interface of the gate insulating film 6 is the number density (total number) of nitrogen atoms in a thickness range t1 from a second depth position d2 at which the carbon (C) concentration of the carbon concentration distribution 72 in the depth direction from the gate insulating film 6 to the semiconductor substrate 5 is 1% of the carbon concentration of the semiconductor substrate 5 (SiC) to a third depth position d3 of about 3 nm in a direction away from the semiconductor substrate 5 toward the upper surface (surface opposite to the semiconductor substrate 5 side) side of the gate insulating film 6. The nitrogen atoms in a portion of the gate insulating film 6 other than the portion P2 in the vicinity of the interface (that is, the portion farther from the semiconductor substrate 5 than is the third depth position d3) do not adversely affect the gate characteristics even when said nitrogen atoms become charge traps. Therefore, the nitrogen concentration distribution may be in any state.

The maximum carbon concentration of the carbon concentration distribution 72 in the depth direction from the gate insulating film 6 to the semiconductor substrate 5 is defined as the carbon concentration of the semiconductor substrate 5 (SiC). In the carbon concentration distribution 72, the second depth position d2 at which the carbon concentration is 1% of the carbon concentration of the semiconductor substrate 5 is assumed to be the interface 9 between the gate insulating film 6 and the semiconductor substrate 5, and a portion at which the carbon concentration is 1% or less of the carbon concentration of the semiconductor substrate 5 is assumed to be the gate insulating film 6. In the gate insulating film 6, the nitrogen concentration from the second depth position d2 to a depth position of about 1.5nm in a direction away from the semiconductor substrate 5 may be lowered by the process at step S6 depicted in FIG. 2. However, since the resolution of SIMS in the depth direction is about 3nm, the component analysis accuracy of SIMS from the sample surface (sputtering surface irradiated with the primary ion beam) to a depth of about 2nm or less is low. Therefore, it is preferable to measure the nitrogen concentration of the gate insulating film 6 in the same thickness range of 3nm as the resolution of SIMS in the depth direction.

Specifically, a ratio (hereinafter, referred to as percentage of N concentration near the interface) of an integral value (hereinafter, referred to as an interface vicinity N integral concentration) of the nitrogen concentration of the portion P2 in the vicinity of the interface of the gate insulating film 6 to an integral value (hereinafter, referred to as a peak N integral concentration) of the nitrogen concentration between full widths at half maximum (FWHM) of the peak P1 of the nitrogen concentration distribution 71 in the depth direction from the gate insulating film 6 to the semiconductor substrate 5 is less than about 0.1. The FWHM of the peak P1 of the nitrogen concentration distribution 71 in the depth direction is a peak width at a portion where the nitrogen concentration is 1/2 (about 7.0×10²⁰ atoms/cm³ in FIG. 17) of the maximum nitrogen concentration (nitrogen concentration at the top of the peak: about 1.4×10²¹ atoms/cm³ in FIG. 17) of the peak P1 of the Gaussian distribution (mountain shape) of the nitrogen concentration distribution 71 in the depth direction. The peak having a Gaussian distribution does not need to be strictly a Gaussian distribution, and may be a peak that may be approximated by a Gaussian distribution or is like a Gaussian distribution.

The nitrogen concentration distribution 71 in the depth direction from the gate insulating film 6 to the semiconductor substrate 5 has a peak P1 of a Gaussian distribution in which the first depth position d1 at which the nitrogen concentration is maximum is set as a apex portion, and the nitrogen concentration decreases from the apex portion toward the opposite side in a direction orthogonal to the front surface of the semiconductor substrate 5. The first depth position d1 is located at the interface 9 between the gate insulating film 6 and the semiconductor substrate 5, or is located closer to the gate insulating film 6 or the semiconductor substrate 5 than is the interface 9. The nitrogen concentration in a portion other than the peak P1 of the nitrogen concentration distribution 71 in the depth direction is equal to or less than the minimum concentration of the peak P1 (the nitrogen concentration at the base of the mountain shape). The carbon concentration distribution 72 in the depth direction from the gate insulating film 6 to the semiconductor substrate 5 has the maximum carbon concentration at the semiconductor substrate 5, has a carbon concentration of 1% of the carbon concentration of the semiconductor substrate 5 at the interface 9 (second depth position d2) between the gate insulating film 6 and the semiconductor substrate 5, and has a carbon concentration of 1% or less of the carbon concentration of the semiconductor substrate 5 at the gate insulating film 6.

As described above, according to the second embodiment, by applying the method of manufacturing the silicon carbide semiconductor device according to the first embodiment, the nitrogen content of the gate insulating film is reduced, the donor level density in the gate insulating film at the level corresponding to the inside of the band gap of SiC and the interface level density at the interface between the gate insulating film and the semiconductor substrate may be reduced, and the nitrogen concentration distribution in the depth direction in the gate insulating film may be optimized. That is, the gate characteristics may also be improved by optimizing the nitrogen concentration distribution in the depth direction in the gate insulating film as described above. In addition, since the nitrogen concentration distribution in the depth direction in the gate insulating film is optimized, the effect of reducing the on-resistance due to an increase in channel mobility may be easily obtained and deterioration of the gate characteristics may be suppressed.

With respect to the silicon carbide semiconductor device 10 (refer to FIG. 1) according to the first embodiment, the nitrogen concentration at the interface 9 between the gate insulating film 6 and the semiconductor substrate 5 and the nitrogen concentration of the portion P2 in the vicinity of the interface of the gate insulating film 6 were verified using the second example and the first comparison example (refer to FIG. 10) described above. As described above, the second example is the MOS capacitor 40 (refer to FIG. 13) in which the gate insulating film 44 is formed according to the method of manufacturing the silicon carbide semiconductor device according to the first embodiment (refer to FIG. 2). The semiconductor substrate 43 and the gate insulating film 44 of the second embodiment correspond to the semiconductor substrate 5 and the gate insulating film 6 of the silicon carbide semiconductor device 10, respectively. The first comparison example is the MOS capacitor 40 in which the gate insulating film 44 is formed by a general gate process when SiC is used as a semiconductor material, and etching of the SiC surface and deposition and oxidation annealing of the Si-containing layer are not performed.

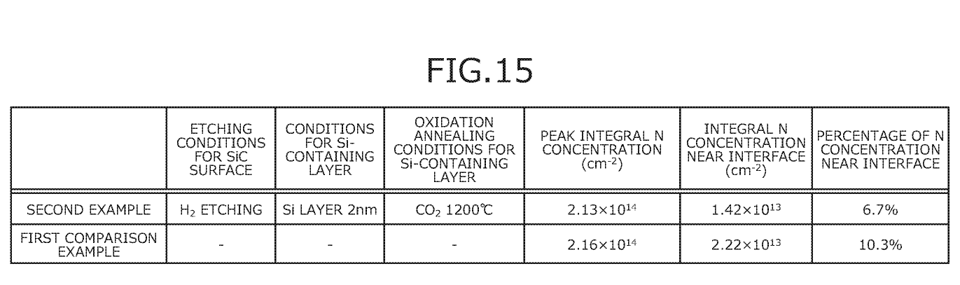

FIG. 15 is a table comparing the number densities of nitrogen atoms in the gate insulating films of the second example and the first comparison example. FIG. 16 is a characteristic diagram depicting results of measurement of the nitrogen concentration distribution and the carbon concentration distribution in the depth direction from the gate insulating film to the semiconductor substrate of the first comparison example. FIG. 17 is a characteristic diagram depicting results of measurement of the nitrogen concentration distribution and the carbon concentration distribution in the depth direction from the gate insulating film to the semiconductor substrate of the second example. FIG. 18 is a comparison diagram depicting the nitrogen concentration distributions depicted in FIGS. 16 and 17 in an overlapping manner. FIG. 15 depicts results of calculation of the peak integral N concentration between the FWHMs of the peaks P1 and P11, the interface vicinity N integral concentration of the portions P2 and P12 in the vicinity of the interface of the gate insulating film 44, and the percentage of N concentration near the interface (=interface vicinity integral N concentration/peak integral N concentration) in the nitrogen concentration distributions 71 and 61 (refer to FIGS. 17 and 16) in the depth direction from the gate insulating film 44 to the semiconductor substrate 43 in the second example and the first comparison example.

For the second example and the first comparison example, quantitative analysis of nitrogen atoms and carbon atoms was performed by SIMS in the depth direction from the upper surface of the gate insulating film 44 (the surface opposite to the semiconductor substrate 43 side) to the inside of the semiconductor substrate 43. As a result, in both the second example and the first comparison example, the first depth positions d1 and d11 at which the maximum nitrogen concentrations of the peaks P1 and P11 of the nitrogen concentration distributions 71 and 61 in the depth direction were at the same position, and the second depth positions d2 and d12 at which the carbon concentration was 1% of the carbon concentration of the semiconductor substrate 43 in the carbon concentration distributions 72 and 62 in the depth direction were at substantially the same position (FIGS. 17 and 16). In both the nitrogen concentration distributions 71 and 61 in the depth direction of the second example and the first comparison example, the maximum nitrogen concentrations at the peaks P1 and P11 were about 1.4×10²¹ atoms/cm³ (FIGS. 17 and 16), and the peak integral N concentrations between the FWHMs of the peaks P1 and P11 were substantially the same (FIG. 15).

On the other hand, from the nitrogen concentration distributions 71 and 61 in the depth direction of the second example and the first comparison example depicted in FIGS. 17 and 16 (FIG. 18), it was confirmed that the nitrogen concentration of the portion P2 in the vicinity of the interface of the gate insulating film 44 of the second example is lower than the nitrogen concentration of the portion P12 in the vicinity of the interface of the gate insulating film 44 of the first comparison example. As depicted in FIG. 15, it was confirmed that the interface vicinity N integral concentration of the portion P2 in the vicinity of the interface of the gate insulating film 44 in the nitrogen concentration distribution 71 in the depth direction of the second example was lower than the interface vicinity N integral concentration of the portion P12 in the vicinity of the interface of the gate insulating film 44 in the nitrogen concentration distribution 61 in the depth direction of the first comparison example. Then, it was confirmed that the N concentration ratio in the vicinity of the interface of the nitrogen concentration distribution 61 in the depth direction of the first comparison example was 10.3%, whereas the N concentration ratio in the vicinity of the interface of the nitrogen concentration distribution 71 in the depth direction of the second example was 6.7% (that is, less than 0.1).

In each of the second example and the first comparison example, the nitrogen concentration of the portions P2 and P12 in the vicinity of the interface of the gate insulating film 44 is the number density of nitrogen atoms in the thickness ranges t1 and t11 from the second depth positions d2 and d12 in which the carbon concentration of the carbon concentration distributions 72 and 62 in the depth direction from the gate insulating film 44 to the semiconductor substrate 43 is 1% of the carbon concentration of the semiconductor substrate 43 to the third depth positions d3 and d13 of about 3nm in the direction away from the semiconductor substrate 43. As described above, since the second depth positions d2 and d12 are substantially the same position, the third depth positions d3 and d13 are also substantially the same position. The horizontal axis (depth) in FIGS. 16 to 18 has a plus scale on the side of the gate insulating film 44 and a minus scale on the side of the semiconductor substrate 43 with reference to the first depth positions d1 and d11 (=0nm). The vertical axis (concentration) in FIGS. 16 to 18 is a logarithmic scale.

As described above, in the fourth example corresponding to the second example (MOSFET in which the gate insulating film 6 is formed under the same conditions as those of the gate insulating film 44 of the second example), the gate characteristics are improved as compared with the fourth comparison example corresponding to the first comparison example (MOSFET to which a general gate process is applied as in the first comparison example) (field effect mobility is increased, fluctuation in gate threshold voltage is suppressed, and etc., refer to FIG. 14). Therefore, it may be said that the interface state density at the interface 9 between the gate insulating film 6 and the semiconductor substrate 5 may be reduced and the gate characteristics may be improved also by optimizing the nitrogen concentration distribution 71 in the depth direction in the gate insulating film 6 (that is, setting the maximum nitrogen concentration of the peak P1 of the nitrogen concentration distribution 71 to 6×10²⁰ atoms/cm³ or more and setting the N concentration ratio in the vicinity of the interface to less than 0.1) by applying the method of manufacturing the silicon carbide semiconductor device according to the first embodiment.

In the first and third examples, as in the second example, both the interface state density at the interface between the gate insulating film 44 and the semiconductor substrate 43 and the donor state density in the gate insulating film 44 are reduced (refer to FIG. 10). Therefore, it is presumed that the nitrogen concentration distribution in the depth direction in the gate insulating film 44 is optimized by applying the method of manufacturing the silicon carbide semiconductor device according to the first embodiment to the first and third examples as in the second example. Also, in the fifth example (MOSFET in which the gate insulating film 6 is formed under the same conditions as those of the gate insulating film 44 of the third example) corresponding to the third example, as in the fourth example, the gate characteristics are improved as compared with the fourth comparison example (refer to FIG. 14). Therefore, it is presumed that the MOSFET in which the gate insulating film 6 is formed under the same conditions as those of the gate insulating film 44 of the first example and the fifth example may obtain the same effects as those of the fourth example.

In the foregoing, the present disclosure is not limited to the embodiments described above, and various modifications not departing from the spirit of the present disclosure are possible. In addition, in each embodiment, while the first conductivity type is assumed to be an n-type and the second conductivity type is assumed to be a p-type, the present disclosure is similarly implemented when the first conductivity type is set to the p-type and the second conductivity type is set to the n-type.

According to the method of manufacturing a silicon carbide semiconductor device and the silicon carbide semiconductor device according to the present disclosure, it is possible to reduce the interface state density at the interface between the gate insulating film and the semiconductor substrate.

As described above, the method of manufacturing a silicon carbide semiconductor device and the silicon carbide semiconductor device according to the present disclosure are useful for power semiconductor devices used in power conversion equipment, power supply devices for various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a silicon carbide semiconductor device, the method comprising:
as a first process, preparing a semiconductor substrate containing silicon carbide and forming a semiconductor region therein, to have a surface of the semiconductor substrate oxidized;
as a second process, etching the oxidized surface of the semiconductor substrate using a gas free of oxygen atoms, thereby exposing a silicon carbide surface at the surface of the semiconductor substrate;
as a third process, depositing a silicon-containing layer containing silicon atoms and free of oxygen atoms to a thickness of 1 nm or more on the surface of the silicon carbide, without exposing the semiconductor substrate to an atmosphere containing oxygen atoms;
as a fourth process, depositing a silicon oxide film constituting a gate insulating film on the silicon-containing layer;
as a fifth process, performing a first heat treatment in an atmosphere containing nitrogen atoms, thereby nitriding the silicon-containing layer and the silicon carbide surface;
as a sixth process, performing a second heat treatment, thereby promoting oxidation of the silicon-containing layer; and
as a seventh process, forming a gate electrode on the gate insulating film after the sixth process.

2. The method according to claim 1, wherein the third process includes depositing the silicon-containing layer to a thickness of not less than 2 nm but not more than 10 nm.

3. The method according to claim 1, wherein the sixth process includes performing the second heat treatment in an atmosphere containing carbon dioxide.

4. The method according to claim 3, wherein the sixth process includes performing the second heat treatment in the atmosphere containing carbon dioxide and nitrogen.

5. The method according to claim 1, wherein
the fifth process includes nitriding the silicon-containing layer, thereby forming a silicon-containing nitride layer, and
the sixth process includes promoting oxidation of the silicon-containing nitride layer after the fifth process.

6. The method according to claim 1, wherein
the sixth process includes promoting the oxidation of the silicon-containing layer, thereby forming a silicon-containing oxide layer, and
the fifth process includes nitriding the silicon carbide surface in contact with the silicon-containing oxide layer.

7. The method according to claim 1, wherein the fifth process includes performing the first heat treatment using nitric oxide gas or nitrous oxide gas, thereby oxynitriding the silicon-containing layer and the silicon carbide surface.

8. The method according to claim 1, further comprising after the third process but before the fourth process:
depositing a field oxide film on the silicon-containing layer; and forming an opening in a portion of the field oxide film and exposing the silicon-containing layer through the opening, wherein
the fourth process includes depositing the silicon oxide film on the silicon-containing layer through the opening in the field oxide film.

9. The method according to claim 1, wherein
the forming of a semiconductor region in the first process includes: forming a first semiconductor region of a first conductivity type in the semiconductor substrate; forming a second semiconductor region of a second conductivity type in the semiconductor substrate and between the surface of the semiconductor substrate and the first semiconductor region; and
selectively forming a third semiconductor region of the first conductivity type in the semiconductor substrate and between the surface of the semiconductor substrate and the second semiconductor region, and the third process includes depositing the silicon-containing layer on a portion of the second semiconductor region between the first semiconductor region and the third semiconductor region.

10. A silicon carbide semiconductor device comprising:
a semiconductor substrate containing silicon carbide;
a gate insulating film provided on a surface of the semiconductor substrate; and
a gate electrode provided on the gate insulating film, ; the gate electrode being configured to form a surface channel in a vicinity of the surface of the semiconductor substrate, facing the gate electrode across the gate insulating film, in response to a gate voltage applied to the gate electrode, wherein
a donor level density in the gate insulating film from an energy at a lower end of a conduction band of the silicon carbide to a level deeper by a predetermined energy less than a band gap of the silicon carbide is less than 1×10¹¹ cm⁻² and
an interface state density at an interface between the gate insulating film and the semiconductor substrate is 1×10¹¹ cm⁻²/eV or less.

11. The silicon carbide semiconductor device according to claim 10, wherein the donor level density in the gate insulating film from the energy at the lower end of the conduction band of the silicon carbide to a level deeper by 2.82eV is less than 1×10¹¹ cm⁻².

12. The silicon carbide semiconductor device according to claim 10, further comprising:
a first semiconductor region of a first conductivity type, provided in the semiconductor substrate; a second semiconductor region of a second conductivity type, provided in the semiconductor substrate and between the surface of the semiconductor substrate and the first semiconductor region; and a third semiconductor region of the first conductivity type, selectively provided in the semiconductor substrate and between the surface of the semiconductor substrate and the second semiconductor region, wherein
the surface channel is formed in a portion of the second semiconductor region between the first semiconductor region and the third semiconductor region.

13. The silicon carbide semiconductor device according to claim 10, wherein
a nitrogen concentration distribution in a depth direction from the gate insulating film to the semiconductor substrate exhibits a Gaussian distribution and has a peak where a nitrogen concentration is maximum at a predetermined first depth position, the nitrogen concentration of the gate insulating film is 6×10²⁰ atoms/cm³ or more and has a maximum concentration at the interface with the semiconductor substrate according to the peak of the nitrogen concentration distribution, and in the nitrogen concentration distribution, a ratio of an integral value of the nitrogen concentration in a selected range to an integral value of the nitrogen concentration between full widths at half maximums of the peak is less than 0.1, the selected range being from
a second depth position at which a carbon concentration of a carbon concentration distribution in the depth direction from the gate insulating film to the semiconductor substrate is 1% of the carbon concentration of the semiconductor substrate,
to
a third depth position of 3 nm in a thickness direction of the semiconductor substrate.
